(19) United States
(12) Patent Application Publication
(10) Pub. No.: US 2020/0116480 A1
(43) Pub. Date: Apr. 16, 2020

(54) SUBSTRATE CLEANING METHOD, SUBSTRATE CLEANING APPARATUS, SUBSTRATE PROCESSING APPARATUS, SUBSTRATE PROCESSING SYSTEM, MACHINE LEARNING DEVICE, AND PREDICTION DEVICE

(71) Applicant: EBARA CORPORATION, Tokyo (JP)

(72) Inventor: Shohei Shima, Tokyo (JP)

(21) Appl. No.: 16/596,051

(22) Filed: Oct. 8, 2019

(30) Foreign Application Priority Data
Oct. 10, 2018 (JP) 2018-191930

(51) Int. Cl. G01B 21/30; G01Q 60/38; B82Y 35/00; H01L 21/67; G01Q 10/06

(52) U.S. Cl. CPC G01B 21/30; G01Q 60/38; G01Q 10/065; H01L 21/67046; B82Y 35/00

(57) ABSTRACT

A substrate cleaning method which can determine an appropriate replacement time of a cleaning tool is disclosed. The substrate cleaning method includes: rubbing a cleaning tool against a substrate in the presence of a cleaning liquid while supplying the cleaning liquid onto the substrate to thereby clean a surface of the substrate; acquiring surface data representing surface properties of the cleaning tool in a wet condition by use of an atomic force microscope after performing cleaning of the surfaces of a predetermined number of substrates; and comparing the surface data with a predetermined threshold to thereby determine a replacement time of the cleaning tool.

### CROSS REFERENCE TO RELATED APPLICATION

This document claims priority to Japanese Patent Application Number 2018-191930 filed Oct. 10, 2018, the entire contents of which are hereby incorporated by reference.

### BACKGROUND

Conventionally, as a method of cleaning a surface of a substrate, such as a semiconductor substrate, a glass substrate, and a liquid crystal panel, a scrubbing-cleaning method is used, in which a cleaning tool (for example, roll sponge, or pen sponge) is rubbed against a surface of the substrate, while supplying a cleaning liquid (for example, chemical liquid, or pure water) onto the surface of the substrate. The scrubbing-cleaning is performed by rubbing the cleaning tool against the substrate while supplying the cleaning liquid onto the substrate in a state where at least one of the substrate and the cleaning tool is rotated. For example, after a polishing process of a wafer which is an example of the substrate, a roll sponge (i.e., cleaning tool), which is moved relative to the surface of the wafer, is rubbed against the surface of the substrate while supplying pure water (i.e., cleaning liquid) onto the surface of the wafer, so that particles (i.e., contaminants), such as polishing debris attached to the wafer, abrasive grains contained in a polishing liquid, and resist residue, are removed from the surface of the wafer. The particles that have been removed from the surface of the substrate are accumulated in the cleaning tool, or are discharged from the substrate together with the cleaning liquid.

Such a scrub-cleaning is performed by placing the cleaning tool in direct contact with the surface of the substrate, and therefore, has an advantage of obtaining high removal efficiency of particles, i.e., high cleaning efficiency. On the other hand, with long-term use of the cleaning tool, some particles, once accumulated in the cleaning tool, can come off the cleaning tool during scrub cleaning of the substrate, and may be attached to the surface of the substrate again. Specifically, in the scrub-cleaning, some particles accumulated in the cleaning tool may cause back-contamination of the substrate.

Accordingly, various methods of preventing the issue for the back-contamination of the substrate have been conventionally proposed. For example, Japanese Laid-Open Patent Publication No. 5-317783 discloses a method in which ultrasonic vibrations are applied to a cleaning tool while supplying a cleaning liquid onto the cleaning tool, and Japanese Laid-Open Patent Publication No. 6-5577 discloses a method in which a substrate is cleaned with a cleaning brush in a cleaning liquid to which ultrasonic vibrations applied. Japanese Laid-Open Patent Publication No. 10-1090745 discloses a method in which a cleaning tool and an abutting member are rubbed against each other in a cleaning liquid to which ultrasonic vibrations applied, thereby cleaning the cleaning tool. These methods are effective in removing contaminants accumulated in a relatively superficial layer of the cleaning tool, but are difficult to remove contaminants which have penetrated into an interior of the cleaning tool.

In order to effectively remove particles which have reached to the interior of the cleaning tool, a method has been proposed, in which a cleaning liquid is supplied into the interior of the cleaning tool to discharge the cleaning liquid from the interior to the exterior of the cleaning tool. However, in this method, as a distance from a cleaning liquid supply source to the cleaning tool increases, it becomes difficult to remove the particles from the interior of the cleaning tool.

Further, the present inventors have found by extensive studies that deterioration of the cleaning tool due to long-term use is another factor to cause back-contamination of the substrate. In general, the cleaning tool used for cleaning of the substrate has a porous structure, and resin such as polyvinyl alcohol (PVA) is widely used as a material for the cleaning tool. When such a resin is used to mold a cleaning tool having a porous structure, an exterior layer portion in contact with a mold, and an interior layer inside the exterior layer are formed. The exterior layer formed in a surface of the cleaning tool consists of a hard layer having a thickness of about several pm to about 10 μm, and contains a small number of pores having a diameter as small as several to several tens of μm. In contrast, the interior layer located inside the exterior layer consists of a softer layer than the exterior layer, and contains pores having a relatively large diameter of about ten μm to about 200 μm.

As the scrub-cleaning that rubs the cleaning tool against the substrate is repeated, the hard exterior layer gradually wears, and eventually the interior layer is exposed. Since the interior layer is softer than the exterior layer, and the interior layer has pores whose diameter is larger than that of pores of the exterior layer, the interior layer is prone to wear as compared to the exterior layer. Therefore, when the cleaning tool whose interior layer is exposed is rubbed against the substrate, a number of wear powders are generated, and these wear powders are attached to the surface of the substrate to cause the back-contamination of the substrate.

In this manner, when repeating the scrub-cleaning that rubs the cleaning tool against the substrate, the back-contamination of the substrate may occur due to wear of the surface of the cleaning tool and particles accumulated in the cleaning tool. Further, as the cleaning tool deteriorates, a cleaning efficiency is decreased. In order to prevent the back-contamination and the decrease in cleaning efficiency, it is necessary to replace the cleaning tool with new one at an appropriate time.

In conventional scrub-cleaning apparatuses, a replacement time (i.e., lifetime) of the cleaning tool is determined in advance based on results of experiments which have been previously performed, or empirical rules, and the cleaning tool that this replacement time has come is replaced. Alternatively, in some cases, so-called “sampling inspection” is performed to determine the replacement time of the cleaning tool.

However, in a case where the replacement time of the cleaning tool is determined in advance based on experiments or empirical rules, the cleaning tool can not be replaced with an appropriate time to be replaced. In other words, the necessity of replacement of the cleaning tool cannot be determined with high accuracy. For example, when a usage time of the cleaning tool reaches the replacement time which is determined in advance, the replacement of the cleaning tool may be performed even though the cleaning tool can still be used. Alternatively, in terms of safety, actual replacement time is set to a time slightly shorter than the replacement time which has been determined based on experiments or empirical rules, in some cases.

In the above-mentioned sampling inspection, an inspection interval is set at short-time, thereby enabling the cleaning tool to be replacement at an early stage of back-contamination of the substrate occurring due to the cleaning tool. However, if the inspection interval is set at short-time, the replacement time of the cleaning tool can be determined more accurately, but a throughput of the substrate cleaning apparatus is decreased, and thus cost of manufacturing of the substrate may be increased. On the other hand, if the inspection interval is set to relatively long-time, the replacement time of the cleaning tool that is determined by the sampling inspection may exceed the appropriate time when the cleaning tool should be replaced. If the substrate is scrubbed by the cleaning tool that the replacement time has already come, back-contamination of the substrate may occur and a yield may be reduced.

The present inventors have found by extensive studies that a replacement time of the cleaning tool should be determined by observing surface properties of the cleaning tool under actual use conditions. For example, the pores of the cleaning tool in wet condition where the cleaning tool is wet by the cleaning liquid are swollen compared to those of the cleaning tool in dry condition. Accordingly, even if the surface properties of the cleaning tool in dry condition are observed, it is difficult to determine an appropriate replacement time of the cleaning tool.

Further, in conventional observation methods, data about surface properties of the cleaning tool can be observed only with micrometer-level resolution. However, recently, there is a tendency that sizes of particles to be cleaned decrease greatly, and particles whose sizes are greatly small have a high adhesion to the substrate. Such micronized particles that adhere to the surface of the substrate are particles that have a diameter equal to or smaller than 1 μm, for example, a diameter equal to or smaller than 100 nm. Accordingly, in order to determine the appropriate replacement time of the cleaning tool based on the surface properties of the cleaning tool, it has become necessary to observe the surface properties of the cleaning tool with nanometer-level resolution.

### SUMMARY OF THE INVENTION

According to embodiments, there are provided a substrate cleaning method and a substrate cleaning apparatus which can determine an appropriate replacement time of a cleaning tool. Further, according to an embodiment, there is provided a substrate processing apparatus incorporating a substrate cleaning apparatus which can determine an appropriate replacement time of a cleaning tool. Further, according to an embodiment, there is provided a substrate processing system provided with at least one substrate processing apparatus. Further, according to an embodiment, there is provided a machine learning device which learns a replacement time of a cleaning tool. Further, there is provided a prediction device for predicting a replacement time of a cleaning tool.

Embodiments, which will be described below, relate to a substrate cleaning method and a substrate cleaning apparatus for scrub-cleaning a substrate, such as a semiconductor substrate, a glass substrate, and a liquid crystal panel, with a cleaning tool, while supplying a cleaning liquid onto the substrate. Further, the below-described embodiments relate to a substrate processing apparatus incorporating such a substrate cleaning apparatus. Further, the below-described embodiments relate to a substrate processing system having at least substrate processing apparatus. Further, the below-described embodiments relate to a machine learning device which learns a replacement time of the cleaning tool. Further, the below-described embodiments relate to a prediction device for predicting a replacement time of a cleaning tool.

In an embodiment, there is provided a substrate cleaning method comprising: rubbing a cleaning tool against a substrate in the presence of a cleaning liquid while supplying the cleaning liquid onto the substrate to thereby clean a surface of the substrate; acquiring surface data representing surface properties of the cleaning tool in a wet condition by use of an atomic force microscope after performing cleaning of the surfaces of a predetermined number of substrates; and comparing the surface data with a predetermined threshold to thereby determine a replacement time of the cleaning tool.

In an embodiment, the surface data is an arithmetic mean roughness of the cleaning tool acquired by use of the atomic force microscope.

In an embodiment, the surface data is a maximum difference in height over the surface of the cleaning tool, and the maximum difference in height is a difference between a maximum value and a minimum value of the surface roughness of the cleaning tool acquired by the atomic force microscope.

In an embodiment, the threshold is an average diameter of particles attached to the surface of the substrate.

In an embodiment, the surface data is a viscoelasticity of the cleaning tool.

In an embodiment, the atomic force microscope includes a probe for scanning the surface of the substrate; and a cantilever to which the probe is mounted, and the cantilever has a spring constant equal to or less than 0.1 N/m.

In an embodiment, the atomic force microscope has a plane resolution equal to or less than 1 μm, and a vertical resolution equal to or less than 300 nm.

In an embodiment, a combination of the surface data and a time point of its acquisition is inputted to a learned model constructed by machine learning, the surface data is compared with an accumulated surface data to thereby predict a time when the surface data reaches the threshold, and the predicted time is added to the time point of acquisition to thereby determine the replacement time of the cleaning tool.

In an embodiment, there is provided a substrate cleaning apparatus comprising: a substrate holder for holding a substrate; a cleaning liquid supply nozzle for supplying a cleaning liquid onto the substrate held by the substrate holder; a cleaning tool which is rubbed against the substrate in the presence of the cleaning liquid to thereby clean the substrate; an atomic force microscope for acquiring surface data representing surface properties of the cleaning tool; and a controller for controlling at least operations of the atomic force microscope; wherein the controller is configured to acquire at least one of surface data representing surface properties of the cleaning tool in a wet condition by use of an atomic force microscope after performing cleaning of the surfaces of a predetermined number of substrates, and compare the surface data with a predetermined threshold to determine a replacement time of the cleaning tool.

In an embodiment, the surface data is an arithmetic mean roughness of the cleaning tool acquired by use of the atomic force microscope.

In an embodiment, the surface data is a maximum difference in height over the surface of the cleaning tool, and the maximum difference in height is a difference between a maximum value and a minimum value of the surface roughness of the cleaning tool acquired by the atomic force microscope.

In an embodiment, the threshold is an average diameter of particles attached to the surface of the substrate.

In an embodiment, the surface data is a viscoelasticity of the cleaning tool.

In an embodiment, the atomic force microscope includes a probe for scanning the surface of the substrate; and a cantilever to which the probe is mounted, and the cantilever has a spring constant equal to or less than 0.1 N/m. In an embodiment, the atomic force microscope has a plane resolution equal to or less than 1 μm, and a vertical resolution equal to or less than 300 nm.

In an embodiment, the controller includes a memory in which a learned model constructed by machine learning is stored; and a processing device configured to perform operations to input a combination of the surface data and a time point of its acquisition, compare the surface data with an accumulated surface data to thereby predict a time when the surface data reaches the threshold, and add the predicted time to the time point of acquisition to thereby determine the replacement time of the cleaning tool.

In an embodiment, there is provided a substrate processing apparatus comprising at least one such substrate cleaning apparatus.

In an embodiment, there is provided a substrate processing system comprising: at least one substrate processing apparatus; a relay device which is connected with the substrate processing apparatus so as to be capable of transmitting and receiving information with each other; and a host control system which is connected with the relay device so as to be capable of transmitting and receiving information with each other.

In an embodiment, there is provided a machine learning device for learning a replacement time of a cleaning tool which is associated with an operating rate of a substrate processing apparatus provided with the cleaning tool, comprising: a state observing unit for observing state quantities of the substrate processing apparatus including at least one of surface data representing surface properties of the cleaning tool in a wet condition, a replacement interval of the cleaning tool, and the operating rate of the substrate processing apparatus; and a learning portion for updating an action-value function for a replacement of the cleaning tool based on the state quantities observed by the state observing unit, wherein the replacement time of the cleaning tool is learned based on the action-value function updated by the learned portion.

In an embodiment, there is provided a prediction device for predicting a replacement time of a cleaning tool which is associated with an operating rate of a substrate processing apparatus provided with the cleaning tool, comprising: a memory in which a learned model constructed by machine learning is stored; and, a processing device configured to perform operations to input, in the learned model, a combination of surface data, which represents surface properties of the cleaning tool in a wet condition and is acquired by an atomic force microscope, and a time point of its acquisition, compare the surface data with an accumulated surface data to thereby predict a time when the surface data reaches the threshold, and add the predicted time to the time point of acquisition to thereby determine the replacement time of the cleaning tool.

According to the above-described embodiments, the surface data of the cleaning tool which has been actually used for scrub-cleaning is acquired by use of the atomic force microscope. Further, the acquired surface is compared with the predetermined threshold to thereby determine the replacement time of the cleaning tool. The atomic force microscope is a microscope that can acquire the surface data of the cleaning tool wet with pure water with nanometer-level resolution. Therefore, the appropriate replacement time can be determined under actual use conditions.

### BRIEF DESCRIPTION OF THE DRAWINGS

FIG. 1 is a plan view showing a whole structure of a substrate processing apparatus incorporating a substrate cleaning apparatus according to an embodiment;

FIG. 2 is a perspective view schematically showing a first cleaning unit;

FIG. 3 is a schematic view showing an example of an interior structure of an atomic force microscope;

FIG. 4A is a schematic view showing a state where a support base is moved to a measurement standby position by a pivot-shaft moving mechanism;

FIG. 4B is a schematic view showing a state where the atomic force microscope is moved to a measurement position;

FIG. 5 is a flowchart illustrating an examplary method of cleaning a substrate in the first cleaning unit;

FIG. 6A is a graph showing a cleaning efficiency to usage time of a roll sponge;

FIG. 6B is a graph showing the number of particles attached to a surface of the substrate to the usage time of the roll sponge;

FIG. 6C is a graph showing a surface roughness of the roll sponge to the usage time of the roll sponge;

FIG. 7A is three-dimensional image data of a surface of a unused roll sponge acquired by the atomic force microscope;

FIG. 7B is a graph showing a profile from a point Pa to a point Pb shown in FIG. 7A;

FIG. 8A is three-dimensional image data of the surface of the roll sponge acquired by the atomic force microscope after performing scrub-cleaning of the predetermined number of substrates with the roll sponge; in

FIG. 8B is a graph showing the profile from a point Pc to a point Pd shown in FIG. 8A;

FIG. 9 is a perspective view schematically showing a second cleaning unit;

FIG. 10 is a perspective view of a cleaning element shown in FIG. 9;

FIG. 11A is a side view showing the cleaning element and a pen sponge;

FIG. 11B is a side view showing the pen sponge when pressed against the cleaning element;

FIG. 12 is a flowchart illustrating an examplary method of cleaning the substrate in the second cleaning unit;

FIG. 13 is a flowchart illustrating another examplary method of cleaning the substrate in the second cleaning unit;

FIG. 14 is a schematic view showing an example of a controller shown in FIG. 1;

FIG. 15 is a schematic view showing an embodiment of an examplary learned model for outputting a replacement time of the cleaning tool;

FIG. 16 is a schematic view showing an example of structure of neural network;

FIG. 17 is a schematic view showing one example of an examplary machine learning device coupled to the controller;

FIG. 18 is a schematic view showing an embodiment of a substrate processing system including at least one substrate processing apparatus; and

FIG. 19 is a schematic view showing another embodiment of the substrate processing system including at least one substrate processing apparatus.

### DESCRIPTION OF EMBODIMENTS

Embodiments will be described with reference to the drawings.

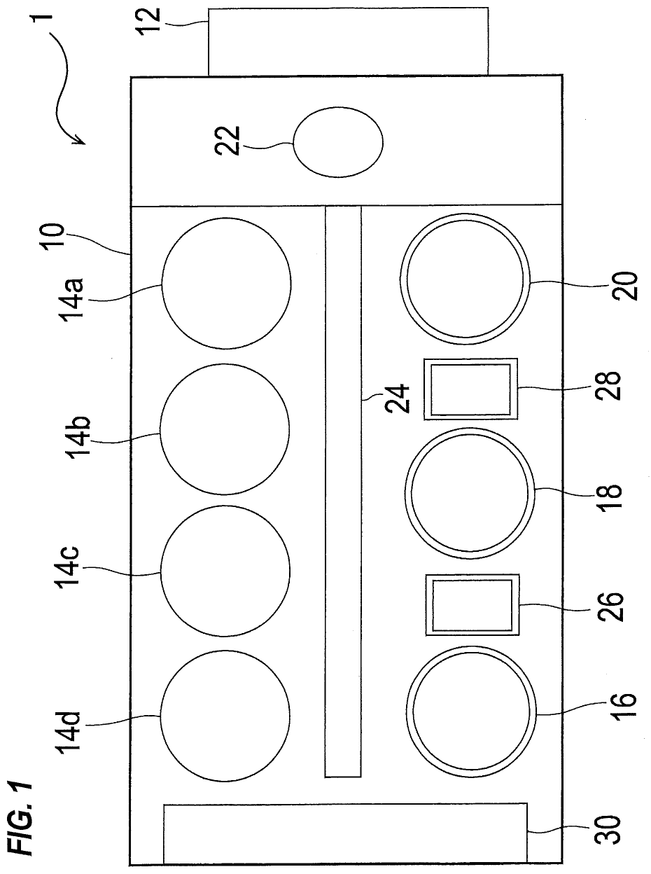

FIG. 1 is a plan view showing a whole structure of a substrate processing apparatus incorporating a substrate cleaning apparatus according to an embodiment. As shown in FIG. 1, the substrate processing apparatus 1 includes an approximately-rectangular housing 10, and a loading port 12 on which a substrate cassette is placed. The substrate cassette houses therein a large number of substrates (wafers). The loading port 12 is disposed adjacent to the housing 10. The loading port 12 can be mounted with an open cassette, a SMIF (Standard Manufacturing Interface) pod, or a FOUP (Front Opening Unified Pod). Each of the SMIF and the FOUP is an airtight container which houses a substrate cassette therein and which, by covering it with a partition wall, can keep its internal environment isolated from an external environment.

In the housing 10, there are disposed a plurality of (e.g., four in this embodiment) polishing units 14a to 14d each for polishing the substrate, a first cleaning unit 16 and a second cleaning unit 18 each for cleaning a polished substrate, and a drying unit 20 for drying a cleaned substrate. The polishing units 14a to 14d are arranged along a longitudinal direction of the substrate processing apparatus 1, and the cleaning units 16, 18 and the drying unit 20 are also arranged along the longitudinal direction of the substrate processing apparatus 1.

Although, in this embodiment, the substrate processing apparatus 1 includes the plurality of polishing units 14a to 14d, the present disclosure is not limited to this embodiment. For example, the substrate processing apparatus 1 may have one polishing unit. Further, the substrate processing apparatus 1 may include a bevel polishing unit for polishing a peripheral portion (which is also referred as “bevel portion”) of the substrate, instead of a plurality of or one polishing unit, or in addition to a plurality of or one polishing unit. Alternatively, the substrate processing apparatus 1 may include a plating tank (or plating apparatus) for plating a surface of the substrate, instead of a plurality of or one polishing unit. In this case, the substrate processing apparatus 1 may include one plating tank (or plating apparatus), or may include a plurality of plating tanks (or plating apparatuses). Hereinafter, the substrate processing apparatus 1 shown in FIG. 1 will be described as one example of the substrate processing apparatus according to the embodiments.

A first substrate transfer robot 22 is disposed in an area surrounded by the loading port 12, the polishing unit 14a, and the drying unit 20. Further, a substrate transport unit 24 is disposed parallel to the polishing units 14a to 14d. The first substrate transfer robot 22 receives a substrate, to be polished, from the loading port 12 and transfers the substrate to the substrate transport unit 24, and further receives a dried substrate from the drying unit 20 and returns the dried substrate to the loading port 12.

The substrate transport unit 24 transports a substrate received from the first substrate transfer robot 22, and transfers the substrate between the polishing units 14a to 14d. Each of the polishing units 14a to 14d is configured to polish a surface of a substrate by bringing the substrate into sliding contact with a polishing surface while supplying a polishing liquid (slurry) onto the polishing surface.

A second substrate transfer robot 26 for transporting a substrate between the cleaning units 16, 18 and the substrate transport unit 24 is provided between the first cleaning unit 16 and the second cleaning unit 18. A third substrate transfer robot 28 for transporting a substrate between the second cleaning unit 18 and the drying unit 20 is provided between these units 18, 20. Further, an controller 30 for controlling operations of each of the units of the substrate processing apparatus 1 is provided in the housing 10.

In this embodiment, the first cleaning unit 16 is a substrate cleaning apparatus configured to clean a substrate by scrubbing both a front surface and a rear surface of the substrate with roll sponges in the presence of a chemical liquid. The second cleaning unit 18 is a substrate cleaning apparatus in which a pen-type sponge (pen sponge) is used.

In one embodiment, the second cleaning unit 18 may be a substrate cleaning apparatus configured to clean a substrate by scrubbing both a front surface and a rear surface of the substrate with roll sponges in the presence of a chemical liquid. The drying unit 20 is a spin drying apparatus configured to hold a substrate, eject IPA vapor from a moving nozzle to dry the substrate, and rotate the substrate at a high speed to further dry the substrate.

Although not shown, the first cleaning unit 16 or the second cleaning unit 18 may be a substrate cleaning apparatus configured to emit a two-fluid jet onto a front surface (or rear surface) of the substrate to clean the front surface (or rear surface) of the substrate, and press a roll sponge against the rear surface (or front surface) to thereby scrub-clean the rear surface (or front surface) of the substrate.

The substrate is polished by at least one of the polishing units 14a to 14d. The polished substrate is cleaned by the first cleaning unit 16 and the second cleaning unit 18, and the cleaned substrate is then dried by the drying unit 20. In one embodiment, the polished substrate may be cleaned by either the first cleaning unit 16 or the second cleaning unit 18.

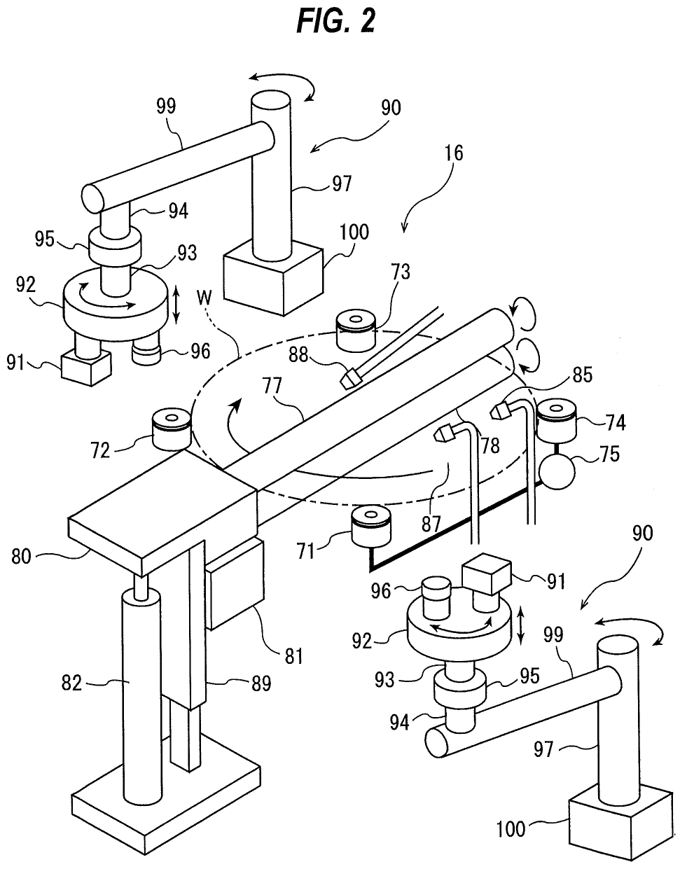

FIG. 2 is a perspective view schematically showing the first cleaning unit (first substrate cleaning apparatus) 16. As shown in FIG. 2, the first cleaning unit 16 includes four holding rollers 71, 72, 73, and 74 for horizontally holding and rotating a substrate (wafer) W, roll sponges (cleaning tools) 77, 78 in a column shape which are brought into contact with an upper surface and a lower surface of the substrate W respectively, cleaning-tool rotating mechanisms 80, 81 for rotating these roll sponges 77, 78 about respective own axes, an upper rinsing-liquid supply nozzle 85 for supplying rinsing liquid (e.g., pure water) onto the upper surface of the substrate W, and an upper chemical-liquid supply nozzle 87 for supplying chemical liquid onto the upper surface of the substrate W. Although not shown in the drawing, the first cleaning unit 16 further includes a lower rinsing-liquid supply nozzle for supplying rinsing liquid (for example, pure water) onto the lower surface of the substrate W, and a lower chemical-liquid supply nozzle for supplying chemical liquid onto the lower surface of the substrate W. In this specification, the chemical liquid and the rinsing liquid may be collectively referred to as cleaning liquid, and the upper chemical-liquid supply nozzle 87 and the rinsing-liquid supply nozzle 85 may be collectively referred to as cleaning-liquid supply nozzle. The roll sponges 77, 78 have a porous structure, respectively. Such roll sponges 77, 78 are, for example, made of a resin, such as PVA, or nylon.

The holding rollers 71, 72, 73, 74 are configured to be movable in directions toward and away from the substrate W by a non-illustrated actuator (e.g., an air cylinder). The two holding rollers 71, 74 of the four holding rollers are coupled to a substrate rotating mechanism 75, which rotates the holding rollers 71, 74 in the same direction. In one embodiment, a plurality of substrate rotating mechanism 75 coupled to each holding rollers 71, 72, 73, 74 may be provided. While the four holding rollers 71, 72, 73, 74 are holding the substrate W, the two holding rollers 71, 74 are rotated to thereby rotate the substrate W about its own axis. In this embodiment, a substrate holder for holding and rotating the substrate W is constituted by the holding rollers 71, 72, 73, 74 and the substrate rotating mechanism 75.

The cleaning-tool rotating mechanism 80 for rotating the upper roll sponge 77 is mounted to a guide rail 89 that guides a vertical movement of the cleaning-tool rotating mechanism 80. The cleaning-tool rotating mechanism 80 is supported by a vertically-moving mechanism 82 so that the cleaning-tool rotating mechanism 80 and the upper roll sponge 77 are moved in the vertical direction by the vertically-moving mechanism 82. Although not shown in the drawings, the cleaning-tool rotating mechanism 81 for rotating the lower roll sponge 78 is also mounted to a guide rail, and the cleaning-tool rotating mechanism 81 and the lower roll sponge 78 are moved in the vertical direction by a vertically-moving mechanism. The vertically-moving mechanism may be a motor-drive mechanism using a ball screw, an air cylinder, or the like. When cleaning the substrate W, the roll sponges 77, 78 are moved in the directions as to come closer to each other until the roll sponges 77, 78 are brought into contact with the upper and lower surfaces of the substrate W respectively. Instead of the roll sponge, a roll brush may be used as the cleaning tool.

Next, a process of cleaning the substrate W will be described. First, the substrate W is rotated about its own axis by the holding rollers 71, 72, 73, 74. Next, the upper chemical-liquid supply nozzle 87 and the lower chemical-liquid supply nozzle (not shown) supply the chemical liquid onto the upper surface and the lower surface of the substrate W, respectively. In this state, the roll sponges (cleaning tools) 77, 78 are brought into sliding contact with the upper and lower surfaces of the substrate W while being rotated about their horizontally-extending axes, thereby scrub-cleaning the upper and lower surfaces of the substrate W. Each of the roll sponges 77, 78 has a length longer than a diameter (or a width) of the substrate W, so that the roll sponges 77, 78 can contact the upper and lower surfaces of the substrate W in their entirety. While the chemical liquid is being supplied onto the substrate W, the pure water is supplied onto the substrate W from a fluid supply nozzle 88.

After the scrub-cleaning, pure water as the rinsing liquid is supplied onto the upper surface and the lower surface of the rotating substrate W while the roll sponges 77, 78 are in sliding contact with the upper and lower surfaces of the substrate W, whereby the substrate W is rinsed.

As shown in FIG. 2, the first cleaning unit 16 further includes two surface measurement mechanisms 90, which measure surface properties of the upper roll sponge 77 and the lower roll sponge 78 respectively. These surface measurement mechanisms 90 are disposed adjacent to the substrate holder constituted by the holding rollers 71, 72, 73, 74 and the substrate rotating mechanism 75. The structure of the surface measurement mechanism 90 for measuring the surface properties of the lower roll sponge 78 is the same as the structure of the surface measurement mechanism 90 for measuring the surface properties of the upper roll sponge 77, except that moving directions of support bases 92 and atomic force microscopes 91 (which will be discussed later) supported respectively by the support bases 92 in the vertical direction are opposite to each other. Therefore, the surface measurement mechanism 90 for measuring the surface properties of the upper roll sponge 77 will be described below, and descriptions of the surface measurement mechanism 90 for measuring the surface properties of the lower roll sponge 78 are omitted.

The surface measurement mechanism 90 serves as a mechanism for measuring surface data that represents the surface properties of the upper roll sponge (cleaning tool) 77 which has been actually used for scrub-cleaning of the substrate W and thus is in wet condition. In this specification, “wet condition” represents a condition where the cleaning tool is wet with the cleaning liquid.

The surface measurement mechanism 90 includes at least an atomic force microscope 91 for acquiring the surface data that represents the surface properties of the upper roll sponge 77 in the wet condition. In general, an atomic force microscope is a microscope which can measure surface properties of a sample, which is in a vacuum, in an atmosphere, or in a liquid, with nanometer-level resolution. Therefore, the afore-mentioned atomic force microscope 91 can measure the surface properties of the upper roll sponge 77 in the wet condition with nanometer-level resolution. The atomic force microscope 91 is connected to the controller 30 (see FIG. 1), and the surface data acquired by the atomic force microscope 91 is sent to the controller 30.

In this embodiment, the surface measurement mechanism 90 further includes the support base 92 configured to support the atomic force microscope 91, a support arm 93 coupled to the support base 92, and an arm-moving mechanism 95 for rotating the support arm 93. The support base 92 is a disk-shaped plate, and supports not only the atomic force microscope 91 but also a lens mechanism 96, which will be discussed later. The atomic force microscope 91 and the lens mechanism 96 are coupled to the arm moving mechanism 95 through the support base 92 and the support arm 93. The support arm 93 is coupled to a center portion of the support base 92 so that a central point of the support base 92 lies on a central axis of the support arm 93. The arm moving mechanism 95 rotates the support arm 93 to thereby rotate the support base 92. As a result, the atomic force microscope 91 and the lens mechanism 96 supported by the support base 92 are rotated about the central axis of the support arm 93.

The surface measurement mechanism 90 further includes a pivot shaft 97, a swing arm 99 coupled to the pivot shaft 97, a connecting arm 94 for connecting the arm moving mechanism 95 to the swing arm 99, and a pivot-shaft moving mechanism 100 for rotating the pivot shaft 97. The pivot-shaft moving mechanism 100 rotates the swing arm 99 through the pivot shaft 97 by a predetermined angle to thereby rotate the arm moving mechanism 95, the support arm 93, the support base 92, and the atomic force microscope 91, which are coupled to the swing arm 99 through the connecting arm 94, about a central axis of the pivot shaft 97. As a result, the support base 92 can be moved between a measurement standby position in which the support base 92 is located above the substrate W and a retreat position in which the support base 92 is located away from the substrate W in a horizontal direction (for example, a lateral position of the substrate holder constituted by the holding rollers 71, 72, 73, 74 and the substrate rotating mechanism 75). In the example shown in FIG. 2, the support base 92 is in the retreat position.

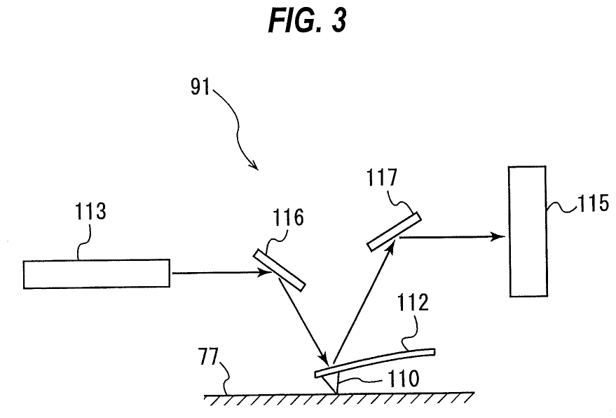

FIG. 3 is a schematic view showing an example of an interior structure of the atomic force microscope 91. The atomic force microscope 91 shown in FIG. 3 includes a probe 110 for scanning the surface of the substrate W, a cantilever 112 to which the probe 110 is mounted, a light source 113 for emitting a laser beam to the cantilever 112, and an optical sensor 115 configured to detect a reflected light which is reflected at a surface of the cantilever 112. The probe 110 and the cantilever 112 may be formed integrally. The atomic force microscope 91 measures the surface properties of the upper roll sponge (cleaning tool) 77 by utilizing a deflection of the cantilever 112 due to an atomic force acting between the probe 110 and the upper roll sponge 77 when the probe 110 mounted to the cantilever 112 is moved closer to the surface of the upper roll sponge 77. More specifically, the probe 110 is scanned over the surface of the upper roll sponge 77 such that the atomic force acting between the probe 110 and the upper roll sponge 77 is kept constant, and a variation in the deflection of the cantilever 112 is detected by use of the optical sensor 115 which receives the reflected light emitted from the light source 113. As a result, the surface properties of the upper roll sponge 77 (for example, uneven shape of the surface of the upper roll sponge 77) can be detected with nanometer-level resolution. In this embodiment, the laser beam emitted from the light source 113 is directed to an upper surface of the cantilever 112 by a mirror 116, and a reflected light from the upper surface of the cantilever 113 is directed to the optical sensor 115 by a mirror 117.

The atomic force microscope 91 is connected to the controller 30 (see FIG. 1), and the surface data which represents the surface properties of the upper roll sponge 77 acquired by the atomic force microscope 91 is sent to the controller 30. Examples of the surface data that can be acquired by the atomic force microscope 91 include arithmetic mean roughness (Ra) of the upper roll sponge 77, maximum difference in height over the surface of the upper roll sponge 77, and viscoelasticity of the surface of the upper roll sponge 77. The maximum difference in height represents a value corresponding to a difference between a maximum value and a minimum value of the surface roughness of the upper roll sponge 77 acquired by the atomic force microscope 91. In one embodiment, the atomic force microscope 91 may acquire root mean squared roughness (RMS) instead of the arithmetic mean roughness, or in addition to the arithmetic mean roughness, and send this root mean squared roughness (RMS) to the controller 30.

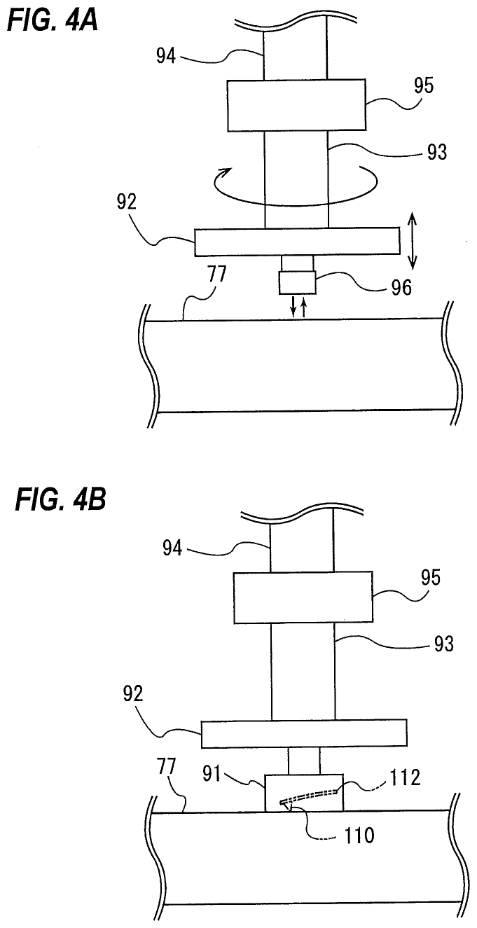

FIG. 4A is a schematic view showing a state where the support base 92 is moved to the measurement standby position by the pivot-shaft moving mechanism 100, and FIG. 4B is a schematic view showing a state where the atomic force microscope 91 is moved to a measurement position.

As described above, the pivot-shaft moving mechanism 100 rotates the swing arm 99 by the predetermined angle, thereby moving the support base 92 to the measurement standby position where the support base 92 is located above the substrate W.

As shown in FIG. 4A, the pivot-shaft moving mechanism 100 rotates the pivot shaft 97 until the lens mechanism 96 supported by the support base 92 reaches a potion above the upper roll sponge 77. In this embodiment, the arm moving mechanism 95 is configured to be able to vertically move the support arm 93, thereby enabling the lens mechanism 96 supported by the support base 92 to be vertically moved with respect to the upper roll sponge 77.

Although not shown, the lens mechanism 96 has a light source (e.g., laser), optical lenses, and an imaging device. In a state where the lens mechanism 96 is adjacent to the upper roll sponge 77, a light is emitted to the upper roll sponge 77 from the light source of the lens mechanism 96 through the optical lenses. When a reflected light from the upper roll sponge 77 reaches an imaging area of the imaging device, the arm moving mechanism 95 moves up and down the support base 92 and the lens mechanism 96 through the support arm 93 such that an image of the surface of the upper roll sponge 77 is focused on the imaging area of the imaging device.

After focusing the image of the surface of the upper roll sponge 77 on the imaging area of the imaging device, the arm moving mechanism 95 rotates the support arm 93 by a predetermined angle, causing the atomic force microscope 91 to face the surface of the upper roll sponge 77. The atomic force microscope 91 and the lens mechanism 96 is mounted to the support base 92 such that, at this time, the atomic force microscope 91 is located at the measurement position (see FIG. 4B), in which the probe 110 of the atomic force microscope 91 can scan the surface of the upper roll sponge 77. Therefore, the lens mechanism 96, the support base 92, the support arm 93, and the arm moving mechanism 95 constitute a positioning mechanism which can automatically adjust a position of the atomic force microscope 91 with respect to the upper roll sponge 77. This positioning mechanism enables the position of the atomic force microscope 91 to be automatically adjusted to the measurement position at which the surface properties of the upper roll sponge 77 can be measured, and thus, the atomic force microscope 91 can automatically measure the surface properties of the upper roll sponge 77.

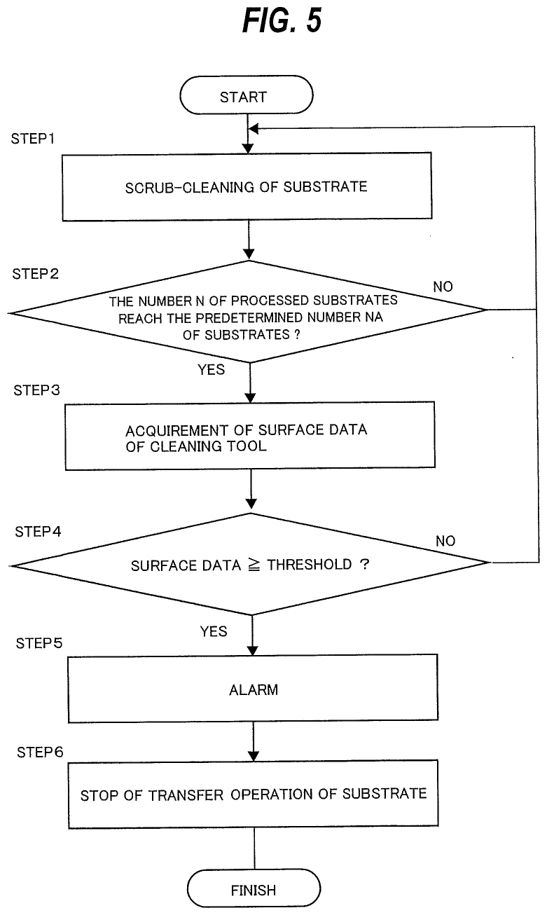

Next, a method of cleaning the substrate in the first cleaning unit 16 will be described below. FIG. 5 is a flowchart illustrating an examplary method of cleaning the substrate in the first cleaning unit 16. The cleaning method shown in FIG. 5 includes a method of determining a replacement time of the upper roll sponge 77. Although, in the first cleaning unit 16, both surfaces of the substrate W are cleaned by the upper roll sponge 77 and the lower roll sponge 78, a method of determining a replacement time of the lower roll sponge 78 is the same as the method of determining the replacement time of the upper roll sponge 77, and duplicate descriptions thereof will be omitted.

As shown in step 1 of FIG. 5, the controller 30 (see FIG. 1) causes the upper roll sponge 77 to be placed in sliding contact with the substrate W transported to the first cleaning unit 16 to thereby scrub-clean the surface of the substrate W. The controller 30 counts the number N of substrates W which have been cleaned after the upper roll sponge 77 is replaced.

When cleaning of the substrate W is finished, the controller 30 determines whether or not the number N of the processed substrates W reaches the determined number NA of substrates (see step 2 of FIG. 5). The predetermined number NA of substrates is a value which is used to determine whether or not the surface properties of the upper roll sponge 77 is measured by the atomic force microscope 91. The controller 30 stores in advance the predetermined number NA of substrates. If the number N of the processed substrate W does not reach the predetermined number NA of substrates (see “NO” in step 2 of FIG. 5), the controller 30, with returning step 1, causes next substrate W to be transported to the first cleaning unit 16 and to perform cleaning of the next substrate W.

When the number N of the processed substrates W reaches the predetermined number NA of substrates (see “YES” in step 2 of FIG. 5), the controller 30 causes the atomic force microscope 91 of the surface measurement mechanism 90 to move, using the above-described method, to the measurement position where the surface properties of the upper roll sponge 77 can be measured, and to acquire the surface data that represents the surface properties of the upper roll sponge 77 (see step 3 of FIG. 5). Examples of this surface data include arithmetic mean roughness (Ra) of the upper roll sponge 77, maximum difference in height over the surface of the upper roll sponge 77, and viscoelasticity of the surface of the upper roll sponge 77. Further, the controller 30 stores the surface data acquired by the atomic force microscope 91 in association with the a time point of its acquisition (that is, a usage time of the upper roll sponge 77 from beginning of use thereof to the acquisition of the surface data by use of the atomic force microscope 91). In one embodiment, the controller 30 may store the surface data acquired by the atomic force microscope 91 in association with the number of substrates which have been scrub-cleaned by the upper roll sponge 77 (that is, the number of substrates which have been scrub-cleaned from beginning of use thereof to the acquisition of the surface data by use of the atomic force microscope 91). The controller 30 repeats this operation each time the atomic force microscope 91 acquires the surface data, and accumulates data consisting of a combination of the surface data of the upper roll sponge 77 and the time point of its acquisition.

Next, the controller 30 compares the surface data acquired by the atomic force microscope 91 of the surface measurement mechanism 90 with a predetermined threshold (see step 4 of FIG. 5). In this embodiment, this threshold is determined in advance by experiments, and stores in advance in the controller 30.

If the surface data is smaller than the threshold (see “NO” in step 4 of FIG. 5), the controller 30, with returning step 1, causes next substrate W to be transported to the first cleaning unit 16 and to perform cleaning for the next substrate W. When the surface data is equal to or more than the threshold, the controller 30 produces an alarm for prompting a replacement of the upper roll sponge 77 (see step 5 of FIG. 5), and together stops a transfer operation of the substrate W to the first cleaning unit 16 (see step 6 of FIG. 5). Therefore, a worker can replace the upper roll sponge 77 with new one before back-contamination of the substrate W due to the upper roll sponge 77 occurs.

In one embodiment, when the surface data is equal to or more than the threshold, the controller 30 may perform an operation of automatically replacing the upper roll sponge 77 with an unused roll sponge which is previously disposed in the first cleaning unit 16. In this case also, the controller 30 preferably produces the alarm indicating that the surface data acquired by the atomic force microscope 91 is equal to or more than the threshold. After replacing automatically the upper roll sponge 77 with unused roll sponge, the controller 30 may cause next substrate to be automatically transported to the first cleaning unit 16 to start cleaning of this substrate, or may stop a transfer operation of next substrate to the first cleaning unit 16. In the case that the transfer operation of next substrate is to be stopped, a worker can check whether or not the unused roll sponge is appropriately attached to the cleaning-tool rotating mechanism 80 (see FIG. 2).

The threshold stored in advance in the controller 30 is an important value for determining an appropriate replacement time of the upper roll sponge 77. Hereinafter, an example of a method of determining the threshold will be described.

In this embodiment, the threshold is determined through experiments which will be described below. As described above, when the scrub-cleaning which rubs the cleaning tool against the substrate is repeated, back-contamination of the substrate may occur due to wear of the surface of the cleaning tool and particles accumulated in the cleaning tool. Therefore, in order to determine the threshold for judging the replacement time of the upper roll sponge 77, it is necessary to consider a cleaning efficiency, a generation amount of particles, and the like.

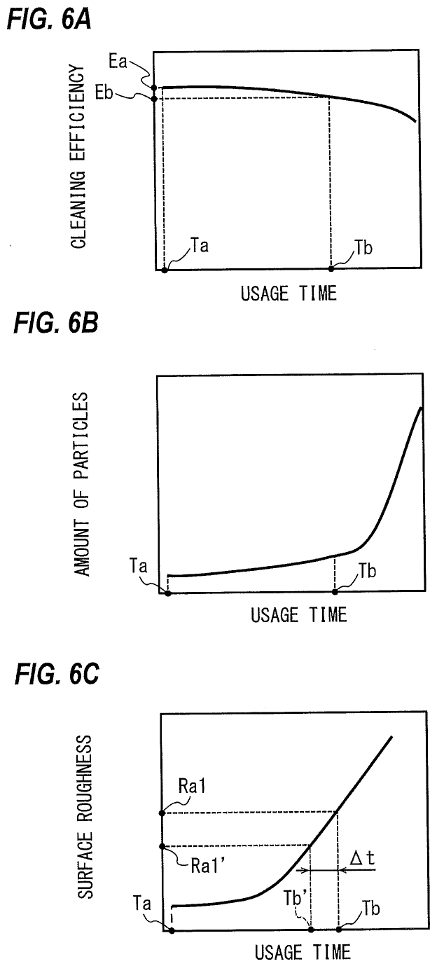

FIGS. 6A, 6B, and 6C are graphs each showing results of experiments which have been made using the same roll sponge as the upper roll sponge 77 shown in FIG. 2. More specifically, FIG. 6A is a graph showing a cleaning efficiency to usage time of the roll sponge, FIG. 6B is a graph showing the number of particles attached to the surface of the substrate to the usage time of the roll sponge, and FIG. 6C is a graph showing a surface roughness of the roll sponge to the usage time of the roll sponge. In experiments, the roll sponge made of polyvinyl alcohol was used, and pure water was used as the cleaning liquid. The surface roughness showing in FIG. 6C was measured by use of an atomic force microscope which is the same as the atomic force microscope 91 shown in FIG. 2.

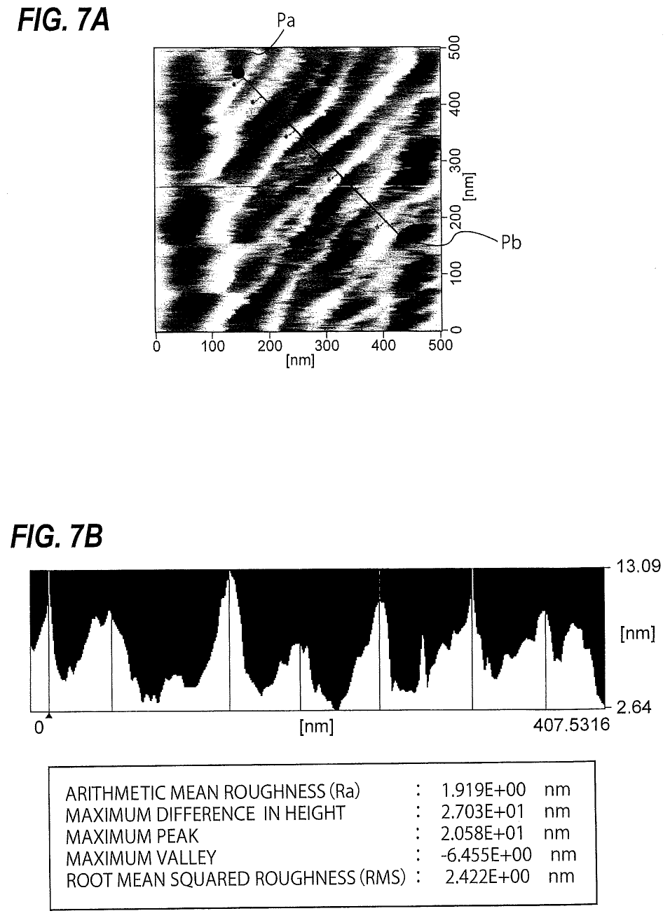

FIG. 7 illustrates results which are obtained by observing surface properties of unused roll sponge wet with pure water by use of the atomic force microscope. More specifically, FIG. 7A is three-dimensional image data of a surface of the unused roll sponge acquired by the atomic force microscope, and FIG. 7B is a graph showing a profile from a point Pa to a point Pb shown in FIG. 7A. The three-dimensional image data and the graph of the surface of the roll sponge shown in FIGS. 7A and 7B respectively, correspond to three-dimensional image data and a profile of the surface of the roll sponge measured at a time point Ta shown in FIGS. 6A to 6C.

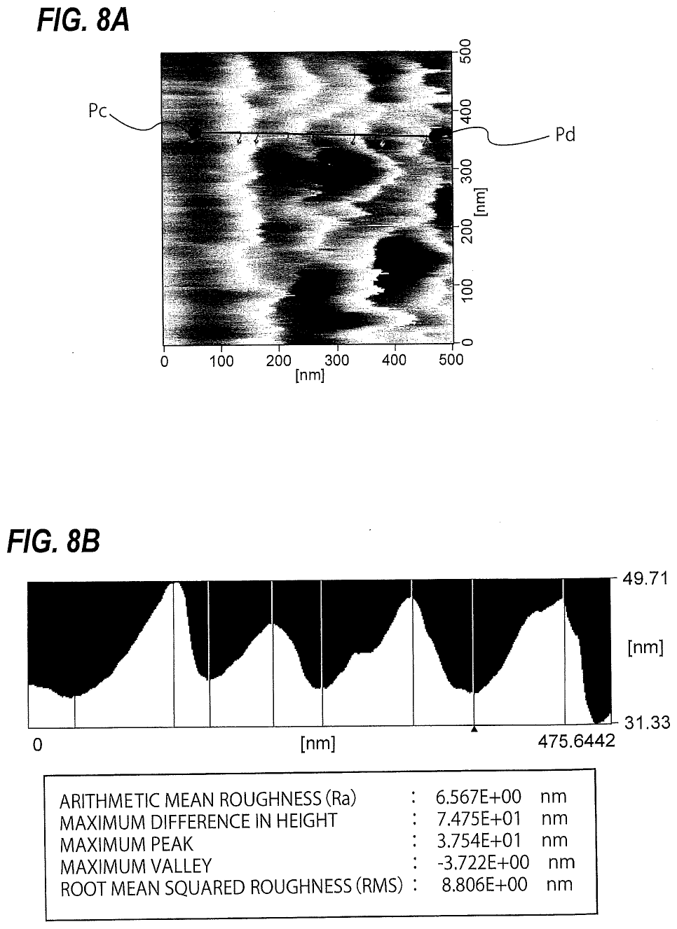

FIG. 8 illustrates results which are obtained by observing, after scrub-cleaning the predetermined number of substrates with the roll sponge whose three-dimensional image data and profile are shown in FIGS. 7A and 7B , surface properties of this roll sponge by use of the atomic force microscope. More specifically, FIG. 8A is three-dimensional image data of the surface of the roll sponge acquired by the atomic force microscope after performing scrub-cleaning of the predetermined number of substrates with the roll sponge, and FIG. 8B is a graph showing the profile from a point Pc to a point

Pd shown in FIG. 8A. When the three-dimensional image data and the profile shown in FIGS. 8A and 8B was acquired by the atomic force microscope, the roll sponge was in wet condition with pure water. The three-dimensional image data and the profile of the surface of the roll sponge shown in FIGS. 8A and 8B correspond to a three-dimensional image data and a profile of the surface of the roll sponge measured at a time point Tb shown in FIGS. 6A to 6B.

As shown in FIG. 7B, arithmetic mean roughness of the unused roll sponge was 1.9 nm, and maximum difference in height was 2.7 nm. As shown in FIG. 8B, arithmetic mean roughness of the roll sponge which had been used for scrub-cleaning until reaching the time point Tb from the time point Ta was 6.6 nm, and maximum difference in height of this roll sponge was 75 nm. In this manner, it was found for the first time that the roll sponge made of PVA has fine irregularities of the order of nanometers on a surface thereof.

It can be seen from the comparison between FIG. 7B and FIG. 8B that, as the roll sponge is used for scrub-cleaning, both of arithmetic mean roughness and maximum difference in height are increased. In this manner, the reason why surface properties, such as arithmetic mean roughness, and maximum difference in height, varies in accordance with usage time of the roll sponge is to be a wearing of the surface of the roll sponge, i.e., to cause the surface of the roll sponge to wear due to the scrub-cleaning.

As shown in FIG. 6A, although the cleaning efficiency decreased with time of the usage time of the roll sponge, a greatly decrease in the cleaning efficiency was not observed. For example, the cleaning efficiency Eb on the time point Tb was little reduced compared to the cleaning efficiency Ea on the time point Ta. The possible reasons for this phenomenon is believed that the roll sponge has a greatly soft property in wet condition with pure water (cleaning liquid), and that, even though a roughness of recesses and protrusions formed on the surface of the roll sponge is increased with time of the usage time, there are protrusions on this surface (see FIG. 7B and FIG. 8B). From these results, the fine irregularities with the order of nanometers are estimated to contribute the fine particles to be removed.

As shown in FIG. 6B, it was found that, when the usage time of the roll sponge reaches the time point Tb, the number of particles attached to the surface of the substrate increases at an accelerated rate. Some of possible reasons for this phenomenon are believed not only to cause particles that once accumulated in the roll sponge to come off the roll sponge and then to be attached to the surface of the substrate again, but also to cause a number of wear powders to be generated from the roll sponge. As described above, when the scrub-cleaning that rubs the roll sponge made of PVA against the substrate is repeated, the soft interior layer, which is located interior to the exterior layer, is exposed. Since the interior layer is softer than the exterior layer, and the interior layer has pores whose diameter is larger than that of pores of the exterior layer, the interior layer is prone to wear as compared to the exterior layer. Therefore, when the cleaning tool whose interior layer is exposed is rubbed against the substrate, a number of wear powders are generated, and these wear powders are attached to the surface of the substrate. Further, as one of possible reasons for causing the number of particles attached to the surface of the substrate to be increased at an accelerated rate, arithmetic mean roughness and maximum difference in height are too large to increase wear of the protrusions, resulting in damaging the protrusions.

In this embodiment, the threshold is determined through the experiments whose results are shown in FIGS. 6A to 6C. More specifically, the time point Tb when the number of particles attached to the surface of the substrate is increased at an accelerated rate is determined by experiments, and then arithmetic mean roughness Ral (see FIG. 6B) corresponding to this time point Tb is determined as the threshold. This time point Tb is, for example, a time point when the differential value of curve shown in FIG. 6B increases sharply. The threshold is stored in advance in the controller 30, and the controller 30 compares arithmetic mean roughness acquired by the atomic force microscope 91 with the threshold (i.e., the arithmetic mean roughness Ral) to determine the replacement time of the upper roll sponge 77. In one embodiment, time point Tb′ may be determined by subtract a predetermined time (Δt) from the time point Tb, and then arithmetic mean roughness Ral′ corresponding to this time point Tb′ may be determined as the threshold.

In the above-described method of determining the threshold, although the arithmetic mean roughness Ral corresponding to the time point Tb is determined as the threshold, the present disclosure is not limited to this embodiment. For example, maximum difference in height corresponding to the time point Tb may be acquired by the atomic force microscope, and this maximum difference in height may be used as the threshold. Alternatively, viscoelasticity of the roll sponge may be acquired by the atomic force microscope, and viscoelasticity corresponding to the time point Tb may be used as the threshold. As with the above-described embodiments, the time point Tb′ may be determined by subtract a predetermined time (At) from the time point Tb, and maximum difference in height or viscoelasticity corresponding to this time point Tb′ may be determined as the threshold. Alternatively, the number of processed substrate W corresponding to the time point Tb may be used as the threshold.

Further, an average diameter of particles (e.g., abrasive grains contained in the polishing liquid) attached to the surface of the substrate may be used as the threshold. More specifically, the replacement time of the roll sponge (i.e., cleaning tool) may be determined by comparing arithmetic mean roughness or maximum difference in height of the surface of the roll sponge, acquired by the atomic force microscope, with the average diameter of particles attached to the surface of the substrate. In this case, a time point when the arithmetic mean roughness or the maximum difference in height of the surface of the roll sponge acquired by the atomic force microscope reaches the average diameter of particles serves as the replacement time of the roll sponge.

As described above, particles attached to the surface of the substrate are removed by the fine irregularities of the order of nanometers formed on the surface of the roll sponge. The present inventors have found by extensive studies that, when the afore-mentioned arithmetic mean roughness or the maximum difference in height is larger than the average diameter of particles, the cleaning efficiency of the substrate is greatly decreased. The reason of this is believed that, when the arithmetic mean roughness or the maximum difference in height is larger than the average diameter of particles, the number of particles accumulated in the roll sponge is increased, and as a result, back-contamination of the substrate occurs due to particles which have come off the roll sponge. Therefore, the average diameter of particles is used as the threshold, and the replacement time of the roll sponge is determined based on the time point when the arithmetic mean roughness or the maximum difference in height reaches a value corresponding to the average diameter of particles, thereby enabling back-contamination of the substrate to be reduced.

According to this embodiment, from the upper roll sponge (cleaning tool) 77 which is disposed in the first cleaning unit (substrate cleaning apparatus) 16, and has been actually used for scrub-cleaning, the surface data representing the surface properties of the upper roll sponge 77 is periodically acquired by use of the atomic force microscope 91. Further, the acquired surface data is compared with the threshold. Specifically, a comparison operation quantitative to the surface data is performed to thereby determine the replacement time of the roll sponge. The atomic force microscope 91 is a microscope that can acquire the surface data of the upper roll sponge 77 wet with the cleaning liquid with nanometer-level resolution. Accordingly, the appropriate replacement time (i.e., lifetime) of the upper roll sponge 77 can be determined under actual use conditions. Further, using a similar method, an appropriate replacement time of the lower roll sponge 78 can be determined.

In a case in which the roll sponge made of resin, such as PVA, or nylon, is in the wet condition with the cleaning liquid, the roll sponge is becoming greatly soft. In other words, the roll sponge in the wet condition has a hardness less than a hardness of the roll sponge in the dry condition. Therefore, if a spring constant of the cantilever 112 (see FIG. 3) of the atomic force microscope 91 is too large, the surface of the upper roll sponge 77 may become deformed when the probe 110 is placed in contact with the upper roll sponge 77. In this case, an accurate surface data of the upper roll sponge 77 cannot be obtained. Accordingly, the spring constant of the cantilever 112 of the atomic force microscope 91 is preferably less than 0.1 N/m. The three-dimensional image data and the profile of the surface of the roll sponge shown in FIG. 7A and FIG. 7B, and the three-dimensional image data and the profile of the surface of the roll sponge shown in FIG. 8A and FIG. 8B were acquired by the atomic force microscope having the cantilever 112 whose spring constant is 0.01 N/m.

As described above, particles attached to the surface of the substrate are particles whose diameters are equal to or less than 1 μm, for example, are equal to or less than 100 nm. Therefore, the atomic force microscope 91 to use for determining the replacement time of the upper roll sponge 77 preferably has a plane resolution equal to or less than 1 μm, and a vertical resolution equal to or less than 300 nm.

Further, in the above-described embodiments, the atomic force microscope 91 acquires the surface data, such as the arithmetic mean roughness (Ra), the maximum difference in height, and the viscoelasticity of the upper roll sponge 77, and the time point when this surface data has become equal to or more than the threshold is determined as the replacement time of the upper roll sponge 77. However, in a case where the atomic force microscope 91 acquires surface data to be decreased with time of the usage time of the upper roll sponge 77, a time point when this surface data has become equal to or less than a threshold is determined as the replacement time of the upper roll sponge 77. Thus, if the atomic force microscope 91 acquires the surface data to be decreased with time of the usage time of the upper roll sponge 77, it should be noticed that the direction of the inequality sign in step 4 of FIG. 5 becomes reversed.

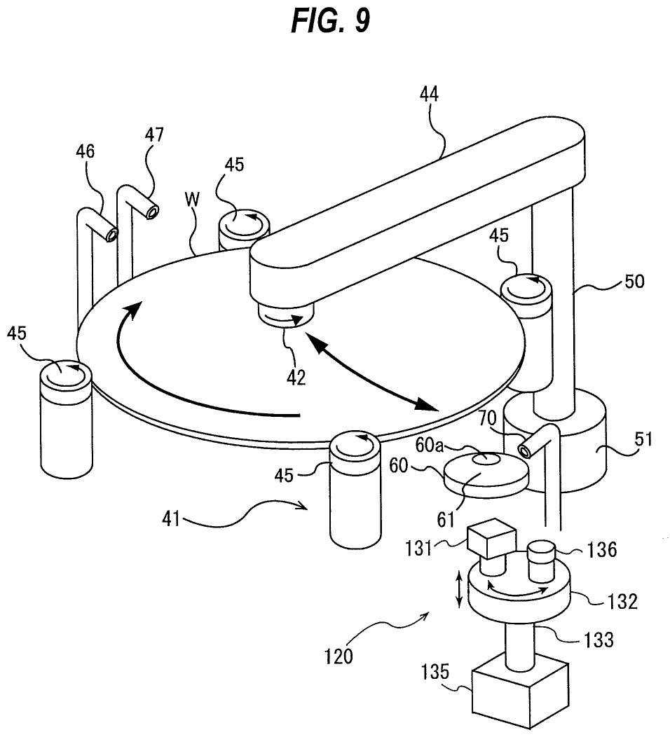

FIG. 9 is a perspective view schematically showing the second cleaning unit 18 of the substrate processing apparatus shown in FIG. 1. The second cleaning unit 18 shown in FIG. 9 is a substrate cleaning apparatus of pen-type. As shown in FIG. 9, this type of substrate cleaning apparatus includes a substrate holder 41 for holding and rotating a substrate (wafer) W, a pen sponge (i.e., cleaning tool) 42 to be brought into contact with a surface of the substrate W, an arm 44 for holding the pen sponge 42, a rinsing liquid supply nozzle 46 for supplying rinsing liquid (typically, pure water) onto the surface of the substrate W, and a cleaning liquid supply nozzle 47 for supplying a chemical liquid onto the surface of the substrate W. The pen sponge 42 is coupled to a cleaning tool rotating mechanism (not shown) provided in the arm 44 so that the pen sponge 42 is rotated about its central axis extending in a vertical direction.

The substrate holder 41 includes a plurality of (four in FIG. 9) rollers 45 each for holding a peripheral portion of the substrate W. These rollers 45 are configured to rotate in the same direction at the same speed. While the rollers 45 are holding the substrate W horizontally, these rollers 45 are rotated, thereby rotating the substrate W about its central axis in a direction indicated by arrow.

The arm 44 is disposed above the substrate W. The pen sponge 42 is coupled to one end of the arm 44, and a pivot shaft 50 is coupled to the other end of the arm 44. The pen sponge 42 is coupled to a cleaning-tool moving mechanism 51 via the arm 44 and the pivot shaft 50. More specifically, the pivot shaft 50 is coupled to the cleaning-tool moving mechanism 51 for causing the arm 44 to pivot. The cleaning-tool moving mechanism 51 is configured to rotate the pivot shaft 50 through a predetermined angle to thereby cause the arm 44 to pivot in a horizontal plane that is parallel to the substrate W. As the arm 44 pivots, the pen sponge 42 supported by the arm 44 is moved in radial direction of the substrate W. The cleaning-tool moving mechanism 51 is further configured to be able to move the pivot shaft 50 in the vertical direction to thereby press the pen sponge 42 against the surface of the substrate W at a predetermined pressure. The pen sponge 42 has a lower surface that constitutes a flat scrubbing surface, which is brought into sliding contact with the surface of the substrate W.

Cleaning of the substrate W is performed as follows. First, the substrate W is rotated about the central axis thereof. Then, the cleaning liquid is supplied from the cleaning liquid supply nozzle 47 onto the upper surface of the substrate W. In this state, the pen sponge 42 is pressed against the upper surface of the substrate W, while the pen sponge 42 is being rotated. Further, the pen sponge 42 oscillates in the radial direction of the substrate W. The pen sponge 42 is placed in sliding contact with the surface of the substrate W in the presence of the cleaning liquid to thereby scrub-clean the substrate W. After the scrub-cleaning, the rinsing liquid is supplied from the rinsing liquid supply nozzle 46 onto the surface of the rotating substrate W to rinse off the cleaning liquid from the substrate W.

The pen sponge 42 has a porous structure. Such a pen sponge 42 is made of a resin which is, for example, PVA. Therefore, as the scrub-cleaning of the substrate (wafer) W is repeated, particles, such as abrasive grains and/or polishing debris, may be accumulated in the pen sponge 42, thus possibly lowering cleaning performance and causing back-contamination of the substrate W to occur. Thus, in order to remove the particles from the pen sponge 42, the second cleaning unit 18 further has a cleaning element 60 for cleaning the pen sponge 42.

As shown in FIG. 9, the cleaning element 60 is located adjacent to the substrate W held by the substrate holder 41. The arm 44 is moved radially outwardly of the wafer W by the cleaning-tool moving mechanism 51 until the pen sponge 42 reaches a position above the cleaning element 60. Then, the pen sponge 42 is pressed against an upper surface (i.e., a cleaning surface) of the cleaning element 60 by the cleaning-tool moving mechanism 51 while the pen sponge 42 is being rotated about its axis. A pure water supply nozzle 70 is provided adjacent to the cleaning element 60 so that pure water is supplied from the pure water supply nozzle 70 to the pen sponge 42 when contacting the cleaning element 60.

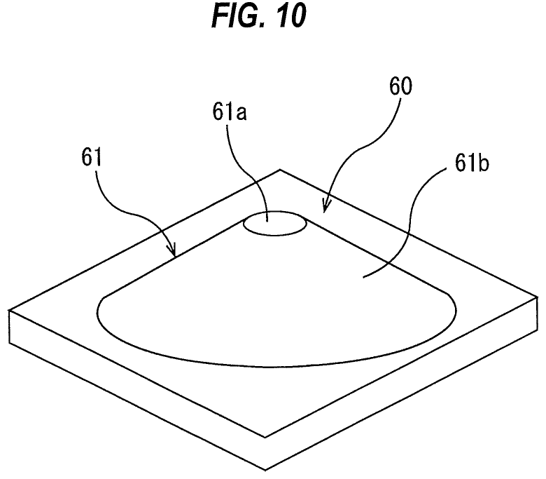

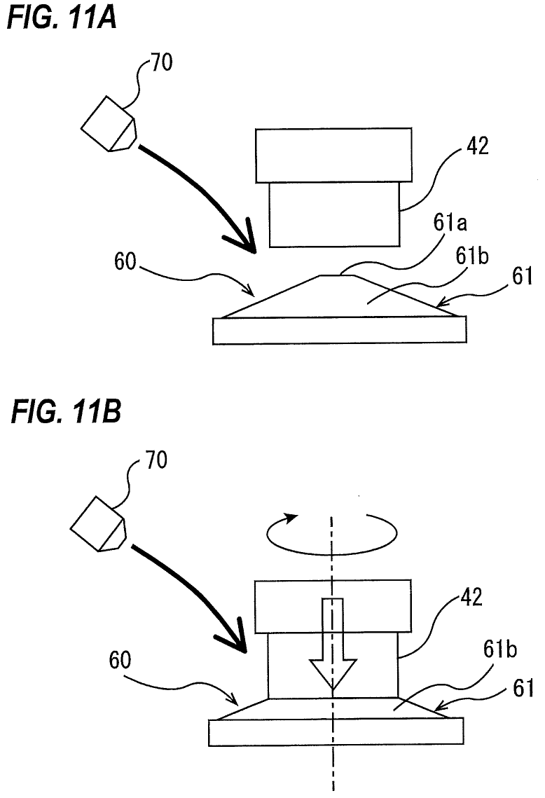

FIG. 10 is a perspective view of the cleaning element 60 shown in FIG. 9. FIG. 11A is a side view showing the cleaning element 60 and the pen sponge 42, and FIG. 11B is a side view showing the pen sponge 42 when pressed against the cleaning element 60. The cleaning element 60 shown in FIG. 10 has a truncated cone shape. The upper surface of the cleaning element 60 constitutes a cleaning surface 61 that is to come in contact with the lower surface (i.e., the scrubbing surface) of the pen sponge 42. The cleaning surface 61 of the cleaning element 60 includes a central portion 61a in a circular shape and a slope portion 61b. The slope portion 61b extends outwardly from the central portion 61a and is inclined downwardly. The slope portion 61b is in an annular shape.

The central portion 61a of the cleaning element 60 protrudes upwardly, and is located at a higher position than other portions (i.e., the slope portion 61b) that surround the central portion 61a. Therefore, when the pen sponge 42 is lowered, a central area of the lower surface of the pen sponge 42 is brought into contact with the protruding central portion 61a of the cleaning surface 61. When the pen sponge 42 is further lowered, a circumferential area of the lower surface of the pen sponge 42 is brought into contact with the slope portion 61b of the cleaning surface 61. In this manner, the entire lower surface of the pen sponge 42 is brought into contact with the cleaning surface 61 of the cleaning element 60. The cleaning element 60 may be made of quartz, resin, polypropylene, or polybutylene terephthalate.

As shown in FIG. 11A and FIG. 11B, the pen sponge 42 is pressed against the cleaning element 60 while the pen sponge 42 is being rotated about the central axis of the pen sponge 42 with its central axis aligned with the central axis of the cleaning element 60. While the pen sponge 42 is pressed against the cleaning element 60, the pure water is supplied from the pure water supply nozzle 70 to the pen sponge 42. In this manner, the pen sponge 42 is cleaned with the pure water while the pen sponge 42 is in sliding contact with the cleaning surface 61 of the cleaning element 60. In one embodiment, the pen sponge 42 may be cleaned while supplying chemical liquid onto the pen sponge 42. Alternatively, the pen sponge 42 may be cleaned while supplying chemical liquid and pure water onto the pen sponge 42.

Since the cleaning element 60 is in the shape of truncated cone, the central portion 61a of the cleaning element 60 lies at a higher position than other portions (i.e., the slope portion 61b) surrounding the central portion 61a. With this configuration, the central area of the pen sponge 42 is pressed more strongly against the cleaning element 60 than other areas of the pen sponge 42, so that particles, such as abrasive grains, polishing debris, and the like, which have entered inside of the central area of the pen sponge 42, can be removed. The particles that have been once removed from the pen sponge 42 flow down rapidly, together with the pure water, on the slope portion 61b of the cleaning element 60. Therefore, the cleaning element 60 can prevent the particles from being reattached to the pen sponge 42.

As shown in FIG. 9, the second cleaning unit (second substrate cleaning apparatus) 16 also has a surface measurement mechanism 120 for measuring surface properties of the pen sponge (i.e., cleaning tool) 42. Structures of the surface measurement mechanism 120, which will not be described particularly, are the same as those of the surface measurement mechanism 90 according to the above-described embodiments, and duplicate descriptions thereof will be omitted.

The surface measurement mechanism 120 shown in FIG. 9 includes at least an atomic force microscope 131 for acquiring surface data that represents the surface properties of the pen sponge 42 in the wet condition. This atomic force microscope 131 has the same structure as that of the atomic force microscope 91 described with reference to FIG. 3. As described above, the atomic force microscope is a microscope which can measure surface properties of a sample, which is in a vacuum, in an atmosphere, or in a liquid, with nanometer-level resolution. Therefore, the atomic force microscope 131 can measure the surface properties of the pen sponge 42 in the wet condition with nanometer-level resolution. The atomic force microscope 131 is also connected to the controller 30 (see FIG. 1), and the surface data acquired by the atomic force microscope 131 is sent to the controller 30.

In this embodiment, the surface measurement mechanism 120 includes a support base 132 configured to support the atomic force microscope 131, a support arm 133 coupled to the support base 132, and an arm-moving mechanism 135 for rotating the support arm 133. In this embodiment also, the support base 132 is a disk-shaped plate, and supports not only the atomic force microscope 131 but also a lens mechanism 136 which has the same structure as that of the above-described lens mechanism 96. The atomic force microscope 131 and the lens mechanism 136 are coupled to the arm moving mechanism 135 through the support base 132 and the support arm 133. The support arm 133 is coupled to a center portion of the support base 132 so that a central point of the support base 132 lies on a central axis of the support arm 93. The arm moving mechanism 135 rotates the support arm 133 to thereby rotate the support base 92. As a result, the atomic force microscope 131 and the lens mechanism 136 supported by the support base 132 are rotated about the central axis of the support arm 133.

In this embodiment, the cleaning-tool moving mechanism 51 rotates the arm 44 until the pen sponge 42 reaches a position above the lens mechanism 136 supported by the support base 132. The arm moving mechanism 135 is configured to be able to vertically move the support arm 133, thereby enabling the lens mechanism 136 supported by the support base 132 to be vertically moved with respect to the pen sponge 42.

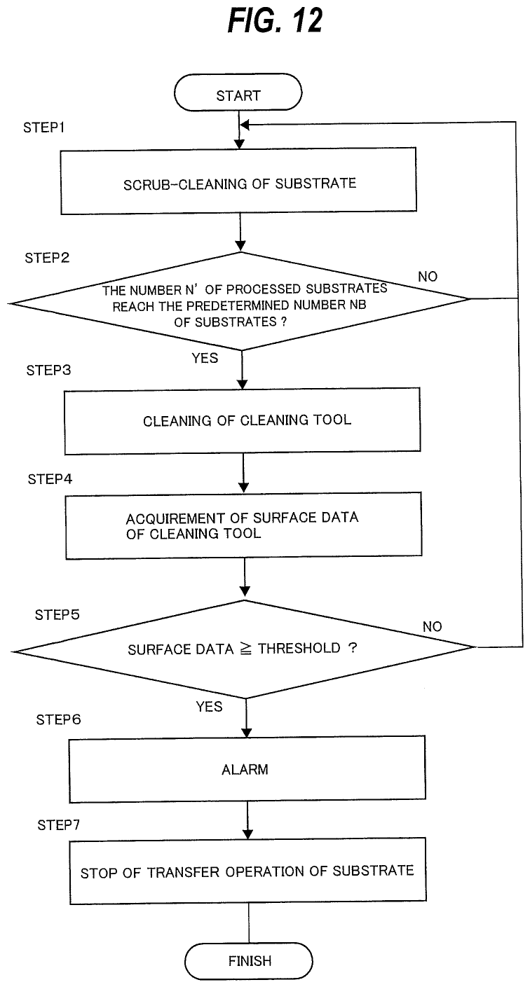

When the pen sponge 42 reach the position above the lens mechanism 136, the arm moving mechanism 135 moves up and down the support base 132 and the lens mechanism 136 through the support arm 133 such that an image of the surface of the pen sponge 42 is focused on an imaging area of an imaging device (not shown) provided in the lens mechanism 136. In this state, the arm moving mechanism 135 rotates the support arm 133 until the atomic force microscope 131 faces the pen sponge 42. After moving up and down the support arm 133 such that the image of the surface of the pen sponge 42 is focused on the imaging area of the imaging device of the lens mechanism 136, the arm moving mechanism 135 rotates the support arm 133 by a predetermined angle, causing the atomic force microscope 131 to face the surface of the pen sponge 42. The atomic force microscope 131 and the lens mechanism 136 is mounted to the support base 132 such that, at this time, the atomic force microscope 131 is located at the measurement position, in which the probe (not shown) of the atomic force microscope 131 can scan the surface of the pen sponge 42. Therefore, the lens mechanism 136, the support base 132, the support arm 133, and the arm moving mechanism 135 constitute a positioning mechanism which can automatically adjust a position of the atomic force microscope 131 with respect to the pen sponge 42. This positioning mechanism enables the position of the atomic force microscope 131 to be automatically adjusted to the measurement position at which the surface properties of the pen sponge 42 can be measured, and thus, the atomic force microscope 131 can automatically measure the surface properties of the pen sponge 42. Next, a method of cleaning the substrate in the second cleaning unit 18 will be described below. FIG. 12 is a flowchart illustrating an examplary method of cleaning the substrate in the second cleaning unit 18. The cleaning method shown in FIG. 12 includes a method of determining a replacement time of the pen sponge 42.

As shown in step 1 of FIG. 12, the controller 30 (see FIG. 1) causes the pen sponge 42 to be placed in sliding contact with the substrate W transported to the second cleaning unit 18, thereby scrub-cleaning the surface of the substrate W. The controller 30 counts the number N′ of substrates W which have been cleaned after the pen sponge 42 is replaced.

When cleaning of the substrate W is finished, the controller 30 determines whether or not the number N′ of the processed substrates W reaches the predetermined number NB of substrates (see step 2 of FIG. 12). The predetermined number NB of substrates is a value which is used to determine whether or not the pen sponge 42 is pressed against the cleaning element 60 to clean the pen sponge 42. The controller 30 stores in advance the predetermined number NB of substrates. As described above, as the scrub-cleaning of the substrate W by use of the pen sponge 42 is repeated, particles, such as abrasive grains, and/or polishing debris, may be accumulated in the pen sponge 42, thus possibly causing back-contamination of the substrate W to occur. Accordingly, after scrub-cleaning the predetermined number NB of substrates by use of the pen sponge 42, the pen sponge 42 is pressed against the cleaning element 60 to thereby clean the pen sponge 42. If the number N′ of the processed substrate W does not reach the predetermined number NB of substrates (see “NO” in step 2 of FIG. 12), the controller 30, with returning step 1, causes next substrate W to be transported to the second cleaning unit 18 and to perform cleaning for the next substrate W.

When the number N′ of the processed substrates W reaches the predetermined number NB of substrates (see “YES” in step 2 of FIG. 12), the controller 30 causes the pen sponge 42 to be pressed against the cleaning element 60, thereby performing the cleaning of the pen sponge 42 (see step 3 of FIG. 12). Next, the controller 30 causes the arm 44 to move until the pen sponge 42 reaches the position above the lens mechanism 136 of the surface measurement mechanism 120. Further, the controller 30 causes the atomic force microscope 131 of the surface measurement mechanism 120 to move, using the above-described method, to the measurement position where the surface properties of the pen sponge 42 can be measured, and to acquire the surface data that represents the surface properties of the pen sponge 42 (see step 4 of FIG. 12). Examples of this surface data include arithmetic mean roughness (Ra) of the pen sponge 42, maximum difference in height over the surface of the pen sponge 42, and viscoelasticity of the surface of the pen sponge 42. Further, the controller 30 stores the surface data acquired by the atomic force microscope 131 in association with the a time point of its acquisition (that is, a usage time of the pen sponge 42 from beginning of use thereof to the acquisition of the surface data by use of the atomic force microscope 131). In one embodiment, the controller 30 may store the surface data acquired by the atomic force microscope 131 in association with the number of substrates which have been scrub-cleaned by the pen sponge 42 (that is, the number of substrates which have been scrub-cleaned from beginning of use thereof to the acquisition of the surface data by use of the atomic force microscope 131). The controller 30 repeats this operation each time the atomic force microscope 131 acquires the surface data, and accumulates data consisting of a combination of the surface data of the pen sponge 42 and the time point of its acquisition (or the number of processed substrates).

Next, the controller 30 compares the surface data acquired by the atomic force microscope 131 of the surface measurement mechanism 120 with a predetermined threshold (see step 5 of FIG. 12). In this embodiment, this threshold is determined in advance by experiments which are described above with reference to FIGS. 6 to 8, and stores in advance in the controller 30.

If the surface data is smaller than the threshold (see “NO” in step 5 of FIG. 12), the controller 30, with returning step 1, causes next substrate W to be transported to the second cleaning unit 18, and to perform cleaning of the next substrate W. When the surface data is equal to or more than the threshold, the controller 30 produces an alarm for prompting a replacement of the pen sponge 42 (see step 6 of FIG. 12), and together stops a transfer operation of the substrate to the second cleaning unit 18 (see step 7 of FIG. 12). Therefore, a worker can replace the pen sponge 42 with new one before back-contamination of the substrate W due to the pen sponge 42 occurs.

In one embodiment, when the surface data is equal to or more than the threshold, the controller 30 may perform an operation of automatically replacing the pen sponge 42 with an unused pen sponge which is previously disposed in the second cleaning unit 18.

In this case also, the controller 30 preferably produces the alarm indicating that the surface data acquired by the atomic force microscope 131 is equal to or more than the threshold. After replacing automatically the pen sponge 42 with unused pen sponge, the controller 30 may causes next substrate to be automatically transported to the second cleaning unit 18 to start cleaning of this substrate, or may stop a transfer operation of next substrate to the second cleaning unit 18. In the case that the transfer operation of next substrate is to be stopped, a worker can check whether or not the unused pen sponge is appropriately attached to the arm 44.

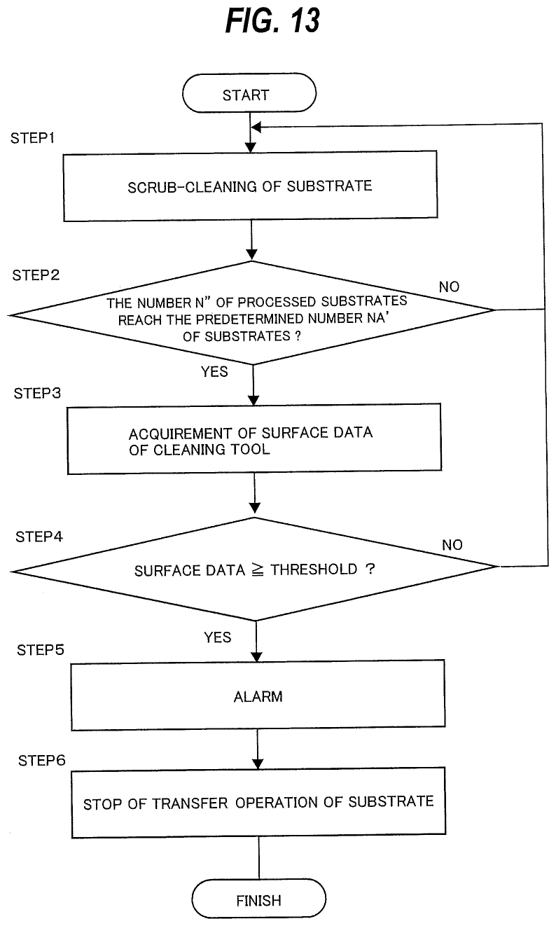

FIG. 13 is a flowchart illustrating another examplary method of cleaning the substrate in the second cleaning unit 18. The substrate cleaning method shown in FIG.

13 includes also a method of determining a replacement time of the pen sponge 42. The substrate cleaning method shown in FIG. 13 is different from the substrate cleaning method shown in FIG. 12 in that the replacement time of the pen sponge 42 is determined regardless of timing of cleaning of the pen sponge 42 by use of the cleaning element 60.

As shown in step 1 of FIG. 13, the controller 30 (see FIG. 1) causes the pen sponge 42 to be placed in sliding contact with the substrate W transported to the second cleaning unit 18, thereby scrub-cleaning the surface of the substrate W. The controller 30 counts the number N″ of substrates W which have been cleaned after the pen sponge 42 is replaced.

When cleaning of the substrate W is finished, the controller 30 determines whether or not the number N″ of the processed substrates W reaches the predetermined number NA′ of substrates (see step 2 of FIG. 13). The predetermined number NA′ of substrates is a value which is used to determine whether or not the surface properties of the pen sponge 42 is measured by the atomic force microscope 131. The controller 30 stores in advance the predetermined number NA′ of substrates. If the number N″ of the processed substrate W does not reach the predetermined number NA′ of substrates (see “NO” in step 2 of FIG. 13), the controller 30, with returning step 1, causes next substrate W to be transported to the second cleaning unit 18 and to perform cleaning for the next substrate W.

When the number N′ of the processed substrates W reaches the predetermined number NA′ of substrates (see “YES” in step 2 of FIG. 13), the controller 30 causes the atomic force microscope 131 of the surface measurement mechanism 120 to move, using the above-described method, to the measurement position where the surface properties of the pen sponge 42 can be measured, and to acquire the surface data that represents the surface properties of the pen sponge 42 (see step 3 of FIG. 13). Examples of this surface data include arithmetic mean roughness (Ra) of the pen sponge 42, maximum difference in height over the surface of the pen sponge 42, and viscoelasticity of the surface of the pen sponge 42. Steps 4 to 6 in the flowchart of FIG. 13 are the same as steps 5 to 7 in the flowchart of FIG. 12, and duplicate descriptions thereof will be omitted.

In the embodiments shown in FIGS. 12 and 13 also, from the pen sponge (cleaning tool) 42 which is disposed in the second cleaning unit (substrate cleaning apparatus) 18, and has been actually used for scrub-cleaning, the surface data representing the surface properties of the pen sponge 42 is periodically acquired by use of the atomic force microscope 131. Further, the acquired surface data is compared with the threshold. Specifically, a comparison operation quantitative to the surface data is performed to thereby determine the replacement time of the pen sponge. The atomic force microscope 131 is a microscope that can acquire the surface data of the pen sponge 42 wet with pure water with nanometer-level resolution. Accordingly, the appropriate replacement time (i.e., lifetime) of the pen sponge 42 can be determined under actual use conditions.

In the embodiments shown in FIGS. 12 and 13 also, a spring constant of the cantilever (not shown) of the atomic force microscope 131 is preferably less than 0.1 N/m. Further, the atomic force microscope 131 preferably has a plane resolution equal to or less than 1 μm, and a vertical resolution equal to or less than 300 nm.

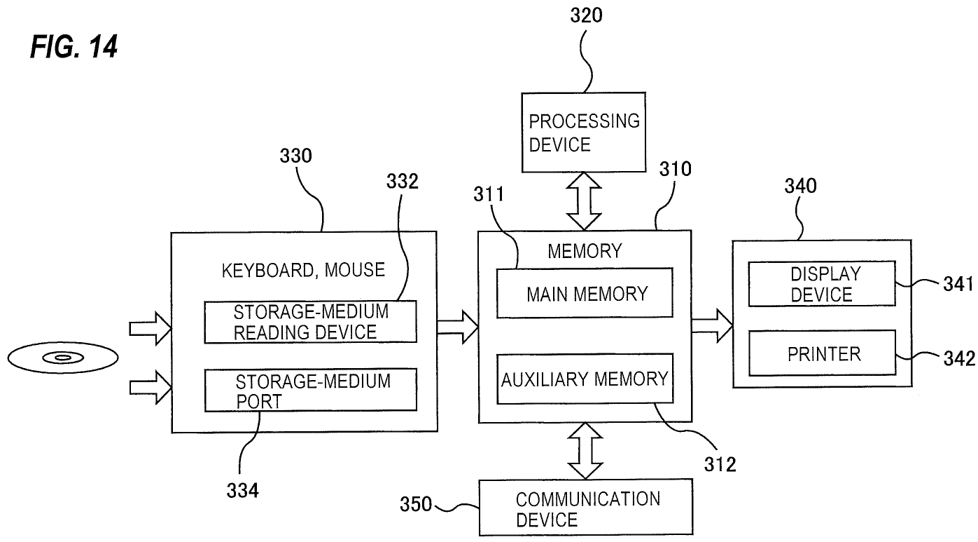

FIG. 14 is a schematic view showing an example of the controller 30 shown in FIG. 1. The controller 30 shown in FIG. 14 is a dedicated or general-purpose computer. In one embodiment, the controller 30 may be a PLC (Programmable Logic Controller), or may be FPGA (Field-Programmable gate array). The controller shown in FIG. 14 includes a memory 310 in which a program and data are stored, a processing device 320, such as CPU (central processing unit) or GPU (graphics processing unit), for performing arithmetic operation according to the program stored in the memory 310, an input device 330 for inputting the data, the program, and various information into the memory 310, an output device 340 for outputting processing results and processed data, and a communication device 350 for connecting to a network, such as the Internet.

The memory 310 includes a main memory 311 which is accessible by the processing device 320, and an auxiliary memory 312 that stores the data and the program therein. The main memory 311 may be a random-access memory (RAM), and the auxiliary memory 312 is a storage device which may be a hard disk drive (HDD) or a solid-state drive (SSD).

The input device 330 includes a keyboard and a mouse, and further includes a storage-medium reading device 332 for reading the data from a storage medium, and a storage-medium port 334 to which a storage medium can be connected. The storage medium is a non-transitory tangible computer-readable storage medium. Examples of the storage medium include optical disk (e.g., CD-ROM, DVD-ROM) and semiconductor memory (e.g., USB flash drive, memory card). Examples of the storage-medium reading device 332 include optical drive (e.g., CD drive, DVD drive) and card reader. Examples of the storage-medium port 334 include USB terminal. The program and/or the data stored in the storage medium is introduced into the computer via the input device 330, and is stored in the auxiliary memory 312 of the memory 310. The output device 340 includes a display device 341 and a printer 342.

The controller 30 operates according to the program electrically stored in the memory 310. Specifically, the controller 30 performs the steps of: operating the surface measurement mechanism 90 (or 120) to acquire the surface data representing the surface properties of the cleaning tool (i.e., the upper roll sponge 77, the lower roll sponge 78, or the pen sponge 42) by use of the atomic force microscope 91 (or 131); and comparing this surface data with the threshold that is stored in advance in the memory 310 to determine the replacement time of the cleaning tool. The data consisting of the combination of the surface data of the cleaning tool and the time point of its acquisition is accumulated in the memory 310 of the controller 30, each time the atomic force microscope 91 acquires the surface data.

The program for causing the controller 30 to perform these steps is stored in a non-transitory tangible computer-readable storage medium. The controller 30 is provided with the program via the storage medium. The controller 30 may be provided with the program via communication network, such as the Internet.

The controller 30 may determine the replacement time of the cleaning tool by use of artificial intelligence (AI). The artificial intelligence performs a machine learning using a neural network, or quantum computing to construct a learned model.

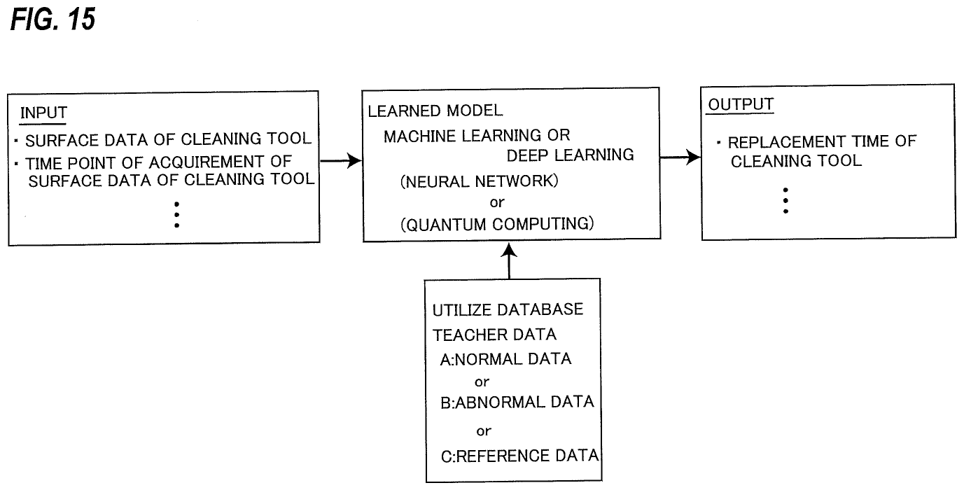

FIG. 15 is a schematic view showing an embodiment of an examplary learned model for outputting a replacement time of the cleaning tool. As shown in FIG. 15, the machine learning for constructing the learned model uses teacher data. The teacher data used for the machine learning is normal data, abnormal data, or reference data. The teacher data is, for example, data set which includes at least the data consisting of combinations of the surface data of the cleaning tool and the time point of its acquisition (or the number of processed substrates). The teacher data is stored in advance in the memory 310 of the controller 30.

As the machine learning, a deep learning method is preferably used. The deep learning method is a neural-network-based learning method, and in the neural network, hidden layers (also referred to middle layers) are multilayered. In the present specification, a machine learning using a neural network constructed of an input layer, two or more hidden layers, and an output layer is referred to as deep learning.

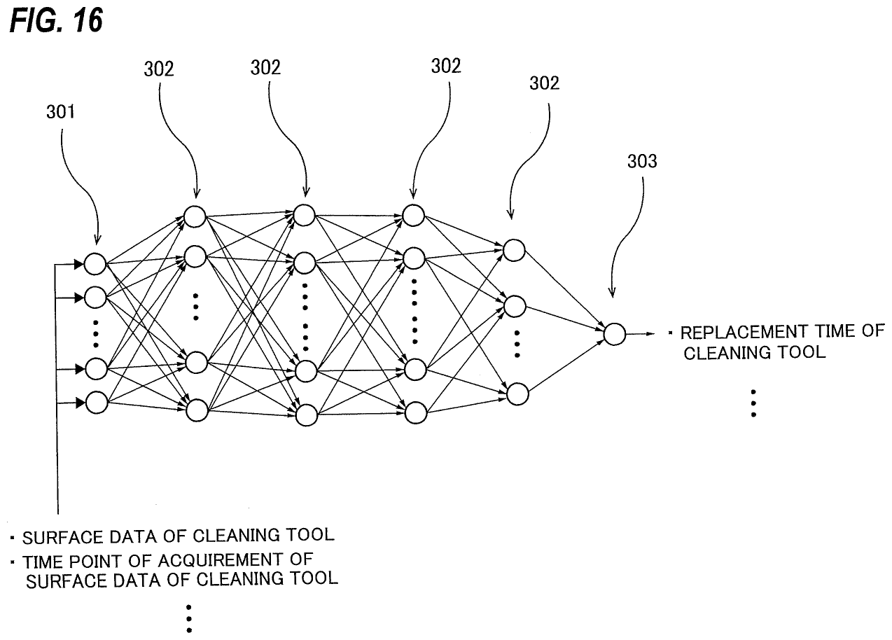

FIG. 16 is a schematic view showing an example of structure of neural network. The learned model is constructed by the deep learning method using the neural network as shown in FIG. 16. The neural network shown in FIG. 16 includes an input layer 301, a plurality of hidden layers 302, and an output layer 303. When normal data is used as the teacher data, the controller 30 adjusts weight parameters for constructing the neural network by use of the normal data to construct the learned model. More specifically, the controller 30 adjusts the weight parameters of the neural network such that, when data including at least the combination of the surface data of the cleaning tool 42, 77, or 78 and the time point (or the number of processed substrate) of its acquisition, which has been prepared for learning, is inputted into the neural network, data corresponding to the appropriate replacement time of the cleaning tool 42, 77, or 78 is outputted from the neural network. Further, the controller 30 preferably checks whether or not data which is, when training data for checking is inputted into the neural network, outputted from the neural network corresponds to teacher data for checking.

The learned model constructed in this manner is stored in the memory 310 (see FIG. 14). The controller 30 operates according to the program electrically stored in the memory 310. Specifically, the processing device 320 of the controller 30 performs operations: to input, in the input layer 301 of the learned model, data including at least the combination of the surface data of the cleaning tool 42, 77, or 78 that is acquired by the atomic force microscope 91 or 131 and the time point (or the number of processed substrate) of its acquisition; predict a time until the surface data of the cleaning tool reaches the threshold from an amount of change between the inputted surface data and the surface data accumulated in the memory 310 of the controller 30; and output this predicted time from the output layer 303. The time point of acquisition of the surface data corresponds to a usage time of the cleaning tool after beginning of use thereof, and thus a value obtained by adding the predicted time to the time point of acquisition corresponds to the replacement time (i.e., lifetime) of the cleaning tool. Therefore, the learned model may output the replacement time of the cleaning tool from the output layer 303.

When the predicted time outputted from the output layer 303 and the replacement time of the cleaning tool are determined to be equivalent to the normal data, the controller 30 accumulates, in the memory 311, these predicted time and replacement time of the cleaning tool as additional teacher data. Further, the controller 30 performs the machine learning (i.e., deep learning) based on the teacher data and the additional teacher data to update the learned model. As a result, accuracy in the predicted time and the replacement time outputted from the learned model can be improved.

In this embodiment, the processing device 320 of the controller 30 performs operation to predict the time when the surface data reaches the threshold by comparing the surface data of the cleaning tool 42, 77, or 78 acquired by the atomic force microscope 91 or 131 with the accumulated surface data stored in the memory 310. Further, the processing device 320 performs operation to add the predicted time to the time point of acquisition of the surface data inputted to the controller 30 thereby determine the replacement time of the cleaning tool 42, 77, or 78. Accordingly, the controller 30 also serves as a prediction device for the replacement time of the cleaning tool 42, 77, or 78. The controller 30 that serves as the prediction device may output the predicted time and the replacement time of the cleaning tool 42, 77, or 78, as the prediction results.

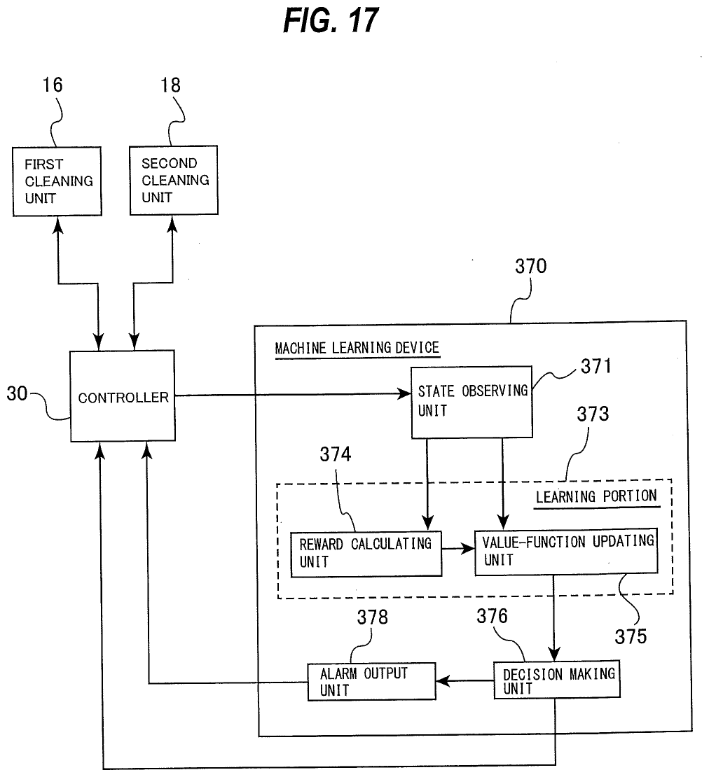

FIG. 17 is a schematic view showing an example of an examplary machine learning device 370 coupled to the controller 30. The machine learning device 370 shown in FIG. 17 is a device for learning the replacement time of the cleaning tool (i.e., the roll sponges 77, 78, and the pen sponge 42) provided in the substrate processing apparatus 1. Although not shown, the controller 30 may have the machine learning device 370 therein, which is shown in FIG. 17. In this case, the machine learning device 370 may implement machine learning using the processing device 320 (see FIG. 14) of the controller 30.

The machine learning device 370 shown in FIG. 17 has a state observing unit 371, a learning portion 373 including a reward calculating portion 374 and a value-function updating portion 375, and a decision making portion 376. As described above, the controller 30 is configured to control operations of the first cleaning unit 16 and the second cleaning unit 18 of the substrate processing apparatus 1. Further, the atomic force microscope 91 of the first cleaning unit 16 and the atomic force microscope 131 of the second cleaning unit 18 are connected to the controller 30. Accordingly, the controller 30 can obtain the surface data of the cleaning tools 77, 78, and 42 acquired by the atomic force microscope 91 and the atomic force microscope 131 respectively. The controller 30 sends to the state observing unit 371, as state quantities of the substrate processing apparatus 1, at least one of the surface data of the cleaning tool 77, 78, or 42 (for example, the arithmetic mean roughness, the maximum difference in height, and viscoelasticity of the cleaning tool 77, 78, or 42), a replacement interval of the cleaning tool 77, 78, or 42, and an operating rate of the substrate processing apparatus 1. The surface data of the cleaning tool 77, 78, and 42 sent to the state observing unit 371 may be or include the three-dimensional image data (as shown in FIGS. 7A and 8A, for example) of the surfaces of the cleaning tool 77, 78, and 42, which can be acquired by the atomic force microscope 91 and the atomic force microscope 131, respectively. The state observing unit 371 observes the state quantities (or change in the state quantities) of the substrate processing apparatus 1 based on the state quantities of the substrate processing apparatus 1 sent from the controller 30.

The reward calculating portion 374 of the learning portion 373 calculates reward based on the state quantities (or change in the state quantities) of the substrate processing apparatus 1 observed by the state observing unit 371, and sends the calculated reward to the value-function updating portion 375. For example, the reward calculating portion 374 is configured to give a smaller reward to the value-function updating portion 375 based on an increase in the surface data (for example, the arithmetic mean roughness) of the cleaning tool 77, 78, or 42, or a decrease in the operating rate of the substrate processing apparatus, and to give a larger reward to the value-function updating portion 375 based on a decrease in the surface data of the cleaning tool 77, 78, or 42, or an increase in the operating rate of the substrate processing apparatus. For example, when an acceptable value of increment of the arithmetic mean roughness, corresponding to the lifetime of the cleaning tool (i.e., any of the upper roll sponge 77, the lower roll sponge 78, and the pen sponge 42), is preset to “A”, the focus is made on a difference between an arithmetic mean roughness f(t0) of the cleaning tool at a time point t0 to begin to use thereof, and an arithmetic mean roughness f(t1) at a time point t1 when a predetermined time has elapsed from beginning of use thereof The reward calculating portion 374 may be configured to give positive reward (e.g., +1) to the value-function updating portion 375 when an absolute value of the difference (=f(t1)−f(t0)) is larger than “A”, and give negative reward (e.g., −1) to the value-function updating portion 375 when the absolute value of the difference (=f(t1)−f(t0)) is equal to or less than “A”.

The value-function updating portion 375 of the learning portion 373 performs updating of a value-function for determining an amount of change in the replacement interval or the replacement time (which is also referred to as “timing for replacement”) of the cleaning tool 77, 78, or 42 from the current state quantities based on the reward given from the reward calculating portion 374. The value-function is, for example, represented as an action-value table for replacing the cleaning tool 77, 78, or 42, and can be stored in a memory (not shown) provided in the machine learning device 370. Alternatively, one example of the value-function is a following equation (1).

Qₜ₊₁(a)=Qₜ(a)+{1/(t+1)}·(rₜ₊₁−Q₂(a)) (1)

wherein a term “Qt(a)” represents an action-value function for t-th action a in a case where the action a has been selected t times heretofore. A t-th reward is represented to “rₜ”. The above-mentioned equation (1) has so to speak a mean of “new value=old value+step size·(target value−old value). As for an initial value, a temporary initial value may be arbitrarily set and updated as needed.

The decision making portion 376 may be configured to determines whether or not the replacement of the cleaning tool 77, 78, or 42 is performed based on the value-function updated by the value-function updating portion 375 and the observed surface data of the cleaning tool, and to send the determined results to the controller 30. For example, the decision making portion 376 may be configured to compare the value function updated based on the observed surface data of the cleaning tool with the value function before updating thereof, determine to replace the cleaning tool if the reward increases, and determine not to replace the cleaning tool if the reward decreases. The controller 30 performs the replacement of the cleaning tool 77, 78, or 42 based on the determined result sent from the decision making portion 376.

As shown in FIG. 17, the machine learning device 370 may include an alarm output portion 378. The alarm output portion 378 sends a signal for outputting an alarm to the controller 30, when the decision making portion 376 determines the replacement of the cleaning tool 77, 78, or 42. The controller 30 which has received the signal from the alarm output portion 378 produces an alarm for prompting the replacement of the cleaning tool 77, 78, or 42. In one embodiment, the alarm output portion 378 itself may produce the alarm for prompting the replacement of the cleaning tool 77, 78, or 42.

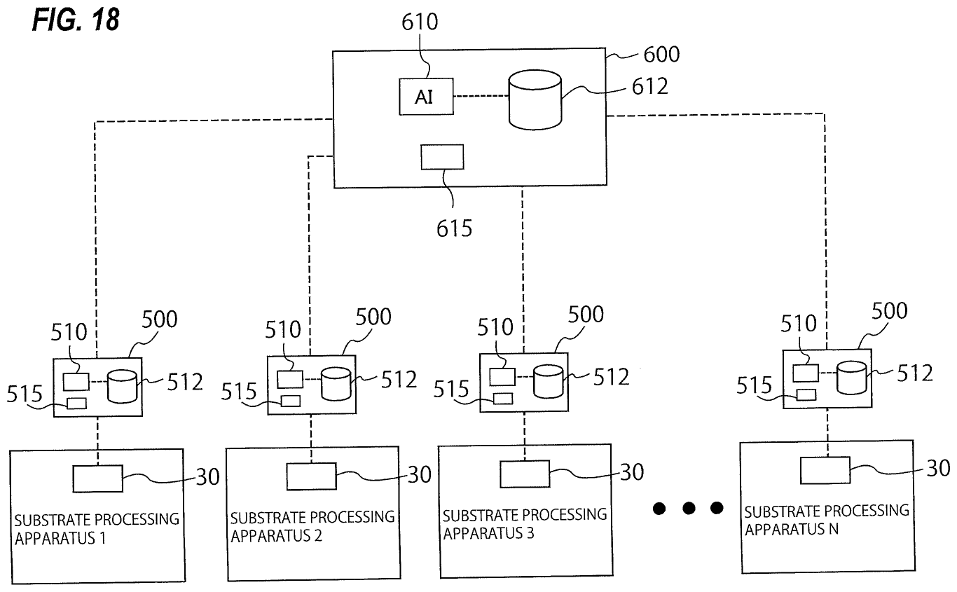

FIG. 18 is a schematic view showing an embodiment of a substrate processing system including at least one substrate processing apparatus. The substrate processing system shown in FIG. 18 includes a plurality of substrate processing apparatuses 1 according to the above-described embodiments, a plurality of relay devices 500 which are coupled to each substrate processing apparatus 1 respectively, and a host control system 600 which is coupled to the plurality of relay devices 500. The relay device 500 serves as a gateway, such as a router, and includes a relay processing device 510, a relay communication device 515, and a relay memory 512. The host control system 600 includes a host processing device 610, a host communication device 615, and a host memory 612.

The communication device 350 (see FIG. 14) of the controller 30 of the substrate processing apparatus 1 is connected with the relay communication device 515 of the relay device 500 by wireless communication (for example, high speed WiFi (registered trademark)) or wire communication so as to be capable of transmitting and receiving information with each other. In this embodiment, each substrate processing apparatus 1 is connected with the host control system 600 by a network (for example, Internet) through the relay device 500.

The host control system 600 may be disposed inside a factory in which at least one substrate processing apparatus 1 is installed, or may be disposed outside the factory in which at least one substrate processing apparatus 1 is installed. If the host control system 600 is disposed inside the factory in which at least one substrate processing apparatus 1 is installed, the host control system 600 may be a host computer disposed inside this factory, or may be a cloud computing system or a fog computing system constructed in this factory. If the host control system 600 is disposed outside the factory in which at least one substrate processing apparatus 1 is installed, the host control system 600 is preferably a cloud computing system or a fog computing system. In this case, the host control system 600 is preferably connected with a plurality of factories in which at least one substrate processing apparatus 1 is installed respectively.

In the embodiment shown in FIG. 18, the host processing device 610 of the host control system 600 determines the afore-mentioned predicted time and the replacement time of the cleaning tool 42, 77, or 78 by use of artificial intelligence (AI). The host memory 612 of the host control system 600 stores in advance the learned model described with reference to FIG. 15 and FIG. 16. The host processing device 610 has a processing device (not shown) which corresponds to the processing device 320 shown in FIG. 14. The processing device of the host processing device 610 performs operations: to retrieve the learned model stored in the host memory 612; to input at least the combination of the surface data of the cleaning tool 42, 77, or 78 acquired by use of the atomic force microscope 91 or 131, and the time point of its acquisition to the learned model; and to output the predicted time and the replacement time of the cleaning tool 42, 77, or 78.

In this embodiment, the controller 30 of each substrate processing apparatus 1 sends data consisting of at least the combination of the surface data of the cleaning tool 42, 77, or 78 acquired by the atomic force microscope 91 or 131, and the time point of its acquisition to the host control system 600 through the relay device 500. The host processing device 610 of the host control system 600 which has received this data performs operations: to input this data to the input layer 301 of the learned model which is stored in the host memory 612, and to output the predicted time and the replacement time of the cleaning tool 42, 77, or 78 from the output layer 303.

The predicted time and the replacement time of the cleaning tool 42, 77, or 78 outputted from the output layer 303 are sent to the substrate processing apparatus 1 through the relay device 500. The controller 30 of the substrate processing apparatus 1 determines the replacement time of the cleaning tool 42, 77, or 78 in accordance with the predicted time and the replacement time of the cleaning tool 42, 77, or 78 sent from the host control system 600.

When the predicted time and the replacement time of the cleaning tool 42, 77, or 78 outputted from the output layer 303 are determined to be equivalent to the normal data, the host processing device 610 of the host control system 600 accumulates, in the host memory 612, these predicted time and replacement time of the cleaning tool 42, 77, or 78 as additional teacher data. Further, the host processing device 610 performs the machine learning (i.e., deep learning) based on the teacher data and the additional teacher data to update the learned model. Huge amount of data consisting of the combination of the surface data of the cleaning tools 42, 77 and 78 and the time points of their acquisitions that is acquired by the plurality of atomic force microscopes 91 and 131 disposed in each of the plurality of substrate processing apparatuses 1 is sent to the host control system 600, and as a result, accuracy in the predicted time and the replacement time outputted from the learned model can be improved in a short period.

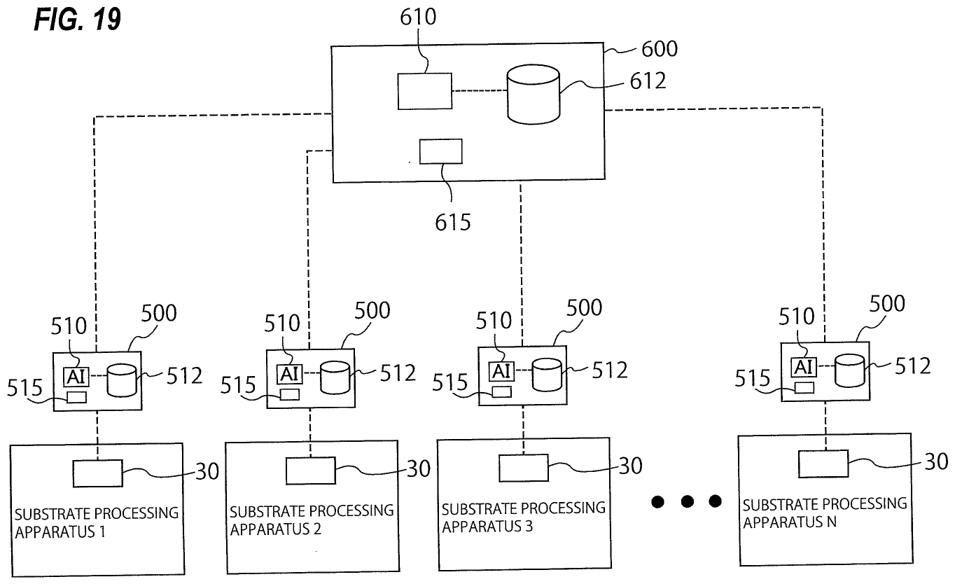

FIG. 19 is a schematic view showing another embodiment of the substrate processing system including at least one substrate processing apparatus. Structures of this embodiment, which will not be described particularly, are the same as those of the embodiment shown in FIG. 18, and duplicate descriptions thereof will be omitted.

In the embodiment shown in FIG. 19, the relay processing device 510 of the relay device 500 determines the afore-mentioned predicted time and the replacement time of cleaning tool 42, 77, or 78 by use of artificial intelligence (AI). In this case, the substrate processing system is constructed as an edge computing system in which the relay device 500 is located in vicinity of the substrate processing apparatus 1. The relay memory 512 of the relay device 500 stores in advance the learned model described with reference to FIG. 15 and FIG. 16. The relay processing device 510 has a processing device (not shown) which corresponds to the processing device 320 shown in FIG. 14. The processing device of the relay processing device 510 performs operations: to retrieve the learned model stored in the relay memory 512; to input at least the combination of the surface data of the cleaning tool 42, 77, or 78 acquired by use of the atomic force microscope 91 or 131, and the time point of its acquisition to the learned model; and to output the predicted time and the replacement time of the cleaning tool 42, 77, or 78. In the substrate processing system according to this embodiment, the relay processing device 510 of the relay device 500 can process diagnosis results for the replacement time of the cleaning tool 42, 77, or 78 at high speed, and output to the substrate processing apparatus 1.

In the above-described embodiments, the substrate cleaning apparatus and the substrate cleaning method of performing scrub-cleaning of the surface of the wafer, which is an example of the substrate, with the cleaning tool while rotating both the wafer and the cleaning tool are described. However, the substrate cleaning apparatus and the substrate cleaning method is limited to these embodiments. For example, during scrub-cleaning of the substrate, at least one of the substrate and the cleaning tool may be rotated. Further, the substrate cleaning method according to the above-described embodiments may be applied to a substrate cleaning apparatus of performing scrub-cleaning of the surface of the substrate, such as glass substrate, or liquid crystal panel with the cleaning tool while supplying a cleaning liquid onto the substrate. For example, when scrub-cleaning of the surface of the glass substrate, the rotating cleaning tool may be brought into sliding contact with the glass substrate moving in a horizontal direction, thereby performing scrub-cleaning of the glass substrate.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A substrate cleaning method comprising:
rubbing a cleaning tool against a substrate in the presence of a cleaning liquid while supplying the cleaning liquid onto the substrate to thereby clean a surface of the substrate;
acquiring surface data representing surface properties of the cleaning tool in a wet condition by use of an atomic force microscope after performing cleaning of the surfaces of a predetermined number of substrates; and
comparing the surface data with a predetermined threshold to thereby determine a replacement time of the cleaning tool.

2. The substrate cleaning method according to claim 1, wherein the surface data is an arithmetic mean roughness of the cleaning tool acquired by use of the atomic force microscope.

3. The substrate cleaning method according to claim 1, wherein the surface data is a maximum difference in height over the surface of the cleaning tool, and the maximum difference in height is a difference between a maximum value and a minimum value of the surface roughness of the cleaning tool acquired by the atomic force microscope.

4. The substrate cleaning method according to claim 1, wherein the threshold is an average diameter of particles attached to the surface of the substrate.

5. The substrate cleaning method according to claim 1, wherein the surface data is a viscoelasticity of the cleaning tool.

6. The substrate cleaning method according to claim 1, wherein the atomic force microscope includes
a probe for scanning the surface of the substrate; and
a cantilever to which the probe is mounted, and
the cantilever has a spring constant equal to or less than 0.1 N/m.

7. The substrate cleaning method according to claim 1, wherein the atomic force microscope has a plane resolution equal to or less than 1 μm, and a vertical resolution equal to or less than 300 nm.

8. The substrate cleaning method according to claim 1, wherein a combination of the surface data and a time point of its acquisition is inputted to a learned model constructed by machine learning,
the surface data is compared with an accumulated surface data to thereby predict a time when the surface data reaches the threshold, and
the predicted time is added to the time point of acquisition to thereby determine the replacement time of the cleaning tool.

9. A substrate cleaning apparatus comprising:
a substrate holder for holding a substrate;
a cleaning liquid supply nozzle for supplying a cleaning liquid onto the substrate held by the substrate holder;
a cleaning tool which is rubbed against the substrate in the presence of the cleaning liquid to thereby clean the substrate;
an atomic force microscope for acquiring surface data representing surface properties of the cleaning tool; and
a controller for controlling at least operations of the atomic force microscope;
wherein the controller is configured to
acquire at least one of surface data representing surface properties of the cleaning tool in a wet condition by use of an atomic force microscope after performing cleaning of the surfaces of a predetermined number of substrates, and
compare the surface data with a predetermined threshold to determine a replacement time of the cleaning tool.

10. The substrate cleaning apparatus according to claim 9, wherein the surface data is an arithmetic mean roughness of the cleaning tool acquired by use of the atomic force microscope.

11. The substrate cleaning apparatus according to claim 9, wherein the surface data is a maximum difference in height over the surface of the cleaning tool, and
the maximum difference in height is a difference between a maximum value and a minimum value of the surface roughness of the cleaning tool acquired by the atomic force microscope.

12. The substrate cleaning apparatus according to claim 9, wherein the threshold is an average diameter of particles attached to the surface of the substrate.

13. The substrate cleaning apparatus according to claim 9, wherein the surface data is a viscoelasticity of the cleaning tool.

14. The substrate cleaning apparatus according to claim 9, wherein the atomic force microscope includes
a probe for scanning the surface of the substrate; and
a cantilever to which the probe is mounted, and
the cantilever has a spring constant equal to or less than 0.1 N/m.

15. The substrate cleaning apparatus according to claim 9, wherein the atomic force microscope has a plane resolution equal to or less than 1 μm, and a vertical resolution equal to or less than 300 nm.

16. The substrate cleaning apparatus according to claim 9, wherein the controller includes
a memory in which a learned model constructed by machine learning is stored; and
a processing device configured to perform operations to input a combination of the surface data and a time point of its acquisition, compare the surface data with an accumulated surface data to thereby predict a time when the surface data reaches the threshold, and add the predicted time to the time point of acquisition to thereby determine the replacement time of the cleaning tool.

17. A substrate processing apparatus comprising a substrate cleaning apparatus according to claim 9.

18. A substrate processing system comprising:
at least one substrate processing apparatus according to claim 17;
a relay device which is connected with the substrate processing apparatus so as to be capable of transmitting and receiving information with each other; and
a host control system which is connected with the relay device so as to be capable of transmitting and receiving information with each other.

19. A machine learning device for learning a replacement time of a cleaning tool which is associated with an operating rate of a substrate processing apparatus provided with the cleaning tool, comprising:
a state observing unit for observing state quantities of the substrate processing apparatus including at least one of surface data representing surface properties of the cleaning tool in a wet condition, a replacement interval of the cleaning tool, and the operating rate of the substrate processing apparatus; and
a learning portion for updating an action-value function for a replacement of the cleaning tool based on the state quantities observed by the state observing unit,
wherein the replacement time of the cleaning tool is learned based on the action-value function updated by the learned portion.

20. A prediction device for predicting a replacement time of a cleaning tool which is associated with an operating rate of a substrate processing apparatus provided with the cleaning tool, comprising:
a memory in which a learned model constructed by machine learning is stored; and,
a processing device configured to perform operations to input, in the learned model, a combination of surface data, which represents surface properties of the cleaning tool in a wet condition and is acquired by an atomic force microscope, and a time point of its acquisition, compare the surface data with an accumulated surface data to thereby predict a time when the surface data reaches the threshold, and add the predicted time to the time point of acquisition to thereby determine the replacement time of the cleaning tool.
